(19) United States
(12) Patent Application Publication
(10) Pub. No.: US 2023/0411562 A1
(43) Pub. Date: Dec. 21, 2023

(54) LIGHT EXTRACTION STRUCTURES FOR LIGHT-EMITTING DIODE CHIPS AND RELATED METHODS

(71) Applicant: CreeLED, Inc., Durham, NC (US)

(72) Inventors: Michael Check, Holly Springs, NC (US); Michael John Bergmann, Erie, CO (US); Alan Wellford Dillon, Bahama, NC (US); Kevin Haberern, Cary, NC (US)

(21) Appl. No.: 17/807,885

(22) Filed: Jun. 21, 2022

(51) Int. Cl. H01L 33/42; H01L 33/58; H01L 33/46; H01L 33/22; H01L 33/00; H01L 33/62; H01L 33/38

(52) U.S. Cl. CPC H01L 33/42; H01L 33/58; H01L 33/46; H01L 2933/0025; H01L 33/005; H01L 33/62; H01L 33/382; H01L 33/22

(57) ABSTRACT

Solid-state lighting devices including light-emitting diodes (LEDs) and more particularly light-extraction features for LED chips and related methods are disclosed. Light-extraction features include structures formed in or on light-emitting surfaces of substrates. Light-extraction features may include repeating patterns of features with dimensions that, along with reduced substrate thicknesses, provide targeted emission profiles for flip-chip structures, such as Lambertian emission profiles. Dimensions include certain height to width ratios for various substrate thicknesses. Additional light-extraction features with smaller dimensions may be formed along portions or side surfaces of larger light-extraction features.

### FIELD OF THE DISCLOSURE

The present disclosure relates to solid-state lighting devices including light-emitting diodes (LEDs) and more particularly to light-extraction features for LED chips and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An active region may be fabricated, for example, from silicon carbide, gallium nitride, gallium phosphide, aluminum nitride, and/or gallium arsenide-based materials and/or from organic semiconductor materials. Photons generated by the active region are initiated in all directions.

Typically, it is desirable to operate LEDs at the highest light emission efficiency, which can be measured by the emission intensity in relation to the output power (e.g., in lumens per watt). A practical goal to enhance emission efficiency is to maximize extraction of light emitted by the active region in the direction of the desired transmission of light. Light extraction and external quantum efficiency of an LED can be limited by a number of factors, including internal reflection. If photons are internally reflected in a repeated manner, then such photons will eventually be absorbed and never provide visible light that exits an LED. To increase the opportunity for photons to exit an LED, it has been found useful to pattern, roughen, or otherwise texture the interface between an LED surface and the surrounding environment to provide a varying surface that increases the probability of refraction over internal reflection and thus enhances light extraction. Reflective surfaces may also be provided to reflect generated light so that such light may contribute to useful emission from an LED chip. LEDs have been developed with internal reflective surfaces or layers to reflect generated light.

As advancements in modern LED technology progress, the art continues to seek improved LEDs and solid-state lighting devices having desirable illumination characteristics capable of overcoming challenges associated with conventional lighting devices.

### SUMMARY

The present disclosure relates to solid-state lighting devices including light-emitting diodes (LEDs) and more particularly to light-extraction features for LED chips and related methods. Light-extraction features include structures formed in or on light-emitting surfaces of substrates. Light-extraction features may include repeating patterns of features with dimensions that, along with reduced substrate thicknesses, provide targeted emission profiles for flip-chip structures, such as Lambertian emission profiles. Dimensions include certain height to width ratios for various substrate thicknesses. Additional light-extraction features with smaller dimensions may be formed along portions or side surfaces of larger light-extraction features.

In one aspect, an LED chip comprises: a substrate comprising a first surface and a second surface that opposes the first surface, the substrate comprising a thickness that is less than or equal to 100 microns (μm); an active LED structure on the first surface of the substrate, the active LED structure being configured to generate light that passes through the substrate when electrically activated; and a plurality of light-extraction features formed at the second surface of the substrate, each light-extraction feature of the plurality of light-extraction features comprising a height and a width, and an average ratio of the height to the width for individual light-extraction features of the plurality of light-extraction features is in a range from 0.3 to 1. In certain embodiments, the average ratio of the height to the width is in a range from 0.3 to 0.7. In certain embodiments, the thickness of the substrate is less than or equal to 75 μm. In certain embodiments, the average ratio of the height to the width is in a range from 0.3 to 0.7, and the thickness of the substrate is less than or equal to 60 μm. In certain embodiments, the substrate comprises sapphire. In certain embodiments, the substrate comprises aluminum nitride. In certain embodiments, the plurality of light-extraction features comprise a same material as the substrate. In certain embodiments, the plurality of light-extraction features are formed in an additional layer that is on the second surface of the substrate. The additional layer may comprise at least one of glass, silicone dioxide, and silicone. In certain embodiments, additional light-extraction features are formed on side surfaces of one or more light-extraction features of the plurality of light-extraction features. In certain embodiments, the plurality of light-extraction features form a repeating pattern across the substrate, and the additional light-extraction features are formed in an irregular arrangement along the side surfaces. In certain embodiments, the substrate and the plurality of light-extraction features are configured to provide an emission profile of light exiting the substrate with an edge emission ratio defined as an emission intensity of light with emission angles greater than 60 degrees from a direction normal to the second surface to a total emission intensity of light for all emission angles from 0 to 90 degrees from the direction normal to the second surface, the edge emission ratio being less than 0.2. In certain embodiments, the LED chip further comprises an antireflective layer on the plurality of light-extraction features. In certain embodiments, a first group of light-extraction features of the plurality of light-extraction features comprises at least one of a different height or width than a second group of light-extraction features of the plurality of light-extraction features. In certain embodiments, the LED chip comprises a lumiphoric material on the plurality of light-extraction features.

In another aspect, an LED chip comprises: a substrate comprising a first surface and a second surface that opposes the first surface, the substrate comprising sapphire with a thickness that is less than or equal to 100 μm; an active LED structure on the first surface of the substrate, the active LED structure being configured to generate light that passes through the substrate when electrically activated; and a plurality of light-extraction features formed at the second surface of the substrate. The LED chip may further comprise an n-contact and a p-contact electrically coupled to the active LED structure, wherein the n-contact and the p-contact are arranged for flip-chip mounting such that the second face of the substrate forms a primary light-emitting face. In certain embodiments, each light-extraction feature of the plurality of light-extraction features comprises a height and a width, and an average ratio of the height to the width for individual light-extraction features of the plurality of light-extraction features is in a range from 0.3 to 1. In certain embodiments, the average ratio of the height to the width is in a range from 0.3 to 0.7, and the thickness of the substrate is less than or equal to 60 μm. In certain embodiments, the plurality of light-extraction features comprise a same material as the substrate. In certain embodiments, the plurality of light-extraction features are formed in an additional layer that is on the second surface of the substrate. In certain embodiments, the additional layer comprises at least one of glass, silicone dioxide, and silicone. In certain embodiments, additional light-extraction features are formed on side surfaces of one or more light-extraction features of the plurality of light-extraction features. In certain embodiments, the plurality of light-extraction features form a repeating pattern across the substrate, and the additional light-extraction features are formed in an irregular arrangement along the side surfaces. The LED chip may further comprise an antireflective layer on the plurality of light-extraction features. In certain embodiments, a first group of light-extraction features of the plurality of light-extraction features comprises at least one of a different height or width than a second group of light-extraction features of the plurality of light-extraction features. In certain embodiments, the LED chip comprises a lumiphoric material on the plurality of light-extraction features.

In another aspect, a method comprises: providing an LED wafer comprising a substrate with a first surface and a second surface that opposes the first surface and an active LED structure on the first surface of the substrate; thinning the substrate to a thickness that is less than or equal to 100 μm; forming a plurality of light-extraction features at the second surface of the substrate after said thinning the substrate; and separating a plurality of LED chips from the LED wafer, each LED chip of the plurality of LED chips comprising a portion of the active LED structure and a portion of the substrate with light-extraction features of the plurality of light-extraction features. In certain embodiments, each light-extraction feature of the plurality of light-extraction features comprises a height and a width, and an average ratio of the height to the width for individual light-extraction features of the plurality of light-extraction features is in a range from 0.3 to 1. In certain embodiments, the average ratio of the height to the width is in a range from 0.3 to 0.7, and the thickness of the substrate is less than or equal to 60 μm. The method may further comprise bonding the LED wafer to a temporary carrier before said thinning the substrate and removing the temporary carrier after said forming the plurality of light-extraction features. In certain embodiments, forming the plurality of light-extraction features comprises etching the substrate through a patterned photomask. The method may further comprise forming additional light-extraction features on side surfaces of one or more light-extraction features of the plurality of light-extraction features.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is an exemplary non-Lambertian emission profile for a light-emitting diode (LED) chip that is flip-chip mounted with a sapphire substrate serving as a light-emitting face.

FIG. 1B is an exemplary Lambertian emission profile for an LED chip that is flip-chip mounted with a sapphire substrate serving as a light-emitting face according to aspects of the present disclosure.

FIG. 2 is a generalized cross-sectional view of an LED chip with a flip-chip orientation and light-extraction features according to aspects of the present disclosure.

FIG. 3 is a cross-sectional view of a representative LED chip arranged with a flip-chip orientation and light-extraction features according to principles of the present disclosure in a similar manner to FIG. 2.

FIG. 4 is a cross-sectional view of an LED chip that is similar to the LED chip of FIG. 3, except light-extraction features are formed in an additional layer on the second surface of the substrate.

FIG. 5 is a cross-sectional view of an LED chip that is similar to the LED chip of FIG. 3, except surfaces of the light-extraction features may include additional light-extraction features formed thereon.

FIG. 6 is a focused ion beam (FIB) image of a portion of an LED chip that is similar to the LED chip of FIG. 5.

FIG. 7A illustrates a single light-extraction feature with labeled dimensions used for simulation parameters according to aspects of the present disclosure. FIG. 7B is a view of a portion of an LED chip that is similar to the LED chip illustrating dimensions used for simulation parameters.

FIG. 7C is a top view of the portion of the LED chip of FIG. 7B illustrating the light-extraction features arranged with an array layout.

FIG. 8 is a plot illustrating relative intensity vs emission angle for a variety of combinations of heights and widths of the light-extraction elements and thicknesses of the substrate as illustrated in FIGS. 6A and 6B.

FIG. 9 is a chart illustrating a figure of merit (FOM) values for evaluating the various thickness values of FIG. 7 for samples that include light-extraction features.

FIG. 10A is contour plot illustrating relationships between heights and widths of the light-extraction elements by total power for all emission angles of FIG. 7.

FIG. 10B is a contour plot illustrating relationships between heights and widths of the light-extraction elements by FOM for all emission angles of FIG. 7.

FIG. 10C is a contour plot illustrating relationships between ratios of the heights to the widths of the light-extraction elements for various thickness values.

FIG. 10D is a plot that comparing height to width ratios by FOM and total power values for different substrate thickness values.

FIG. 11A is a plot showing experimental results comparing relative intensity over emission angle for flip-chip structures and various growth substrate thicknesses without light-extraction features.

FIG. 11B is a view of a portion of the plot of FIG. 11A taken from the box labeled 11B in FIG. 11A.

FIG. 11C is a view of a portion of the plot of FIG. 11A taken from the box labeled 11C in FIG. 11A

FIG. 12 is a plot showing experimental results comparing relative intensity over emission angle for various growth substrate thicknesses without light-extraction features in a manner similar to FIG. 10.

FIG. 13 is a plot comparing experimental results for relative intensity over emission angle for process of record LED chip and an exemplary LED chip fabricated according to FIG. 7.

FIG. 14A is a cross-sectional view of a bulk LED wafer at a fabrication sequence where elements of the LED chip of FIG. 3 have been formed on the substrate.

FIG. 14B is a cross-sectional view of the bulk LED wafer of FIG. 13A at a subsequent fabrication step where the LED wafer is bonded to a temporary substrate by way of a temporary bonding media.

FIG. 14C is a cross-sectional view of the bulk LED wafer of FIG. 13B at a subsequent fabrication step after the substrate has been thinned.

FIG. 14D is a cross-sectional view of the bulk LED wafer of FIG. 13C at a subsequent fabrication step after a photomask is applied to the substrate.

FIG. 14E is a cross-sectional view of the bulk LED wafer of FIG. 13D at a subsequent fabrication step after an etching process has been applied to the substrate and the photomask to form the light-extraction features in the second surface of the substrate.

FIG. 14F is a cross-sectional view of the bulk LED wafer of FIG. 13E at a subsequent fabrication step after the photomask is removed.

FIG. 14G is a cross-sectional view of the bulk LED wafer of FIG. 13F at a subsequent fabrication step after the temporary substrate is removed.

FIG. 14H is a cross-sectional view of the bulk LED wafer of FIG. 13G at a subsequent fabrication step after the bulk LED wafer is mounted on a film frame or die tape.

FIG. 14I is a cross-sectional view of the bulk LED wafer of FIG. 13H at a subsequent fabrication step after the film frame is stretched to separate the individual LED chips.

FIG. 14J is a cross-sectional view at a subsequent fabrication step from FIG. 13I illustrating the individual LED chips separated from one another.

FIG. 15 is a cross-sectional view of an LED chip that is similar to the LED chip of FIG. 2 and further includes an antireflective layer on the first surface of the substrate and on the light-extraction features.

FIG. 16 is a cross-sectional view of an LED chip that is similar to the LED chip of FIG. 2 for embodiments where relative sizes and/or shapes of light-extraction features are variable along the LED chip for tailoring light output of the LED chip.

FIG. 17 is a cross-sectional view of an LED chip that is similar to the LED chip of FIG. 2 for embodiments where the LED chip includes a lumiphoric material on light-extraction features of the substrate.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to light-extraction features for LED chips and related methods. Light-extraction features include structures formed in or on light-emitting surfaces of substrates. Light-extraction features may include repeating patterns of features with dimensions that, along with reduced substrate thicknesses, provide targeted emission profiles for flip-chip structures, such as Lambertian emission profiles. Dimensions include certain height to width ratios for various substrate thicknesses. Additional light-extraction features with smaller dimensions may be formed along portions or side surfaces of larger light-extraction features.

An LED chip typically comprises an active LED structure or region that may have many different semiconductor layers arranged in many different ways. The fabrication and operation of LEDs and their active structures are generally known in the art and are only briefly discussed herein. The layers of the active LED structure may be fabricated using known processes with a suitable process being metal organic chemical vapor deposition. The layers of the active LED structure typically comprise many different layers and generally comprise an active layer sandwiched between n-type and p-type oppositely doped epitaxial layers, all of which are formed successively on a growth substrate. It is understood that additional layers and elements may also be included in the active LED structure, including, but not limited to, buffer layers, nucleation layers, super lattice structures, un-doped layers, cladding layers, contact layers, and current-spreading layers and light extraction layers and elements. The active layer may comprise a single quantum well, a multiple quantum well, a double heterostructure, or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

Different embodiments of the active LED structure may emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 750 nm to 1100 nm, or more.

The LED chip may also be covered with one or more lumiphoric or other conversion materials, such as phosphors, such that at least some of the light from the LED chip is absorbed by the one or more phosphors and is converted to one or more different wavelength spectra according to the characteristic emission from the one or more phosphors. In some embodiments, the combination of the LED chip and the one or more phosphors emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. In some embodiments, one or more phosphors may include yellow phosphor (e.g., YAG:Ce), green phosphor (e.g., LuAg:Ce), and red phosphor (e.g., Ca_{i-x-y}SrₓEu_{y}AlSiN₃) and combinations thereof. One or more lumiphoric materials may be provided on one or more portions of an LED chip and/or a submount in various configurations.

Light emitted by the active layer or region of an LED chip may typically travel in a variety of directions. For targeted directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure may be useful for LED chips having a variety of geometries, including flip-chip geometries. Flip-chip structures for LED chips typically include anode and cathode connections that are made from a same side or face of the LED chip. The anode and cathode side is typically structured as a mounting face of the LED chip for flip-chip mounting to another surface, such as a printed circuit board. In this regard, the anode and cathode connections on the mounting face serve to mechanically bond and electrically couple the LED chip to the other surface. When flip-chip mounted, the opposing side or face of the LED chip corresponds with a light-emitting face that is oriented toward an intended emission direction. In certain embodiments, a growth substrate for the LED chip may form and/or be adjacent to the light-emitting face when flip-chip mounted. During chip fabrication, the active LED structure may be epitaxially grown on the growth substrate.

Growth substrates may typically include many materials, such as sapphire (Al₂O₃), SiC, aluminum nitride (AlN), and GaN. Sapphire is a common substrate for Group III nitrides and has certain advantages, including being lower cost, having established manufacturing processes, and having good light transmissive optical properties. However, sapphire is also known to exhibit guided modes for light propagation that result in some lateral waveguiding within the substrate. In this manner, light emission patterns for sapphire-based flip-chips may not be entirely Lambertian in nature. Rather, increased intensities of light may exit toward perimeter edges of such LED chips.

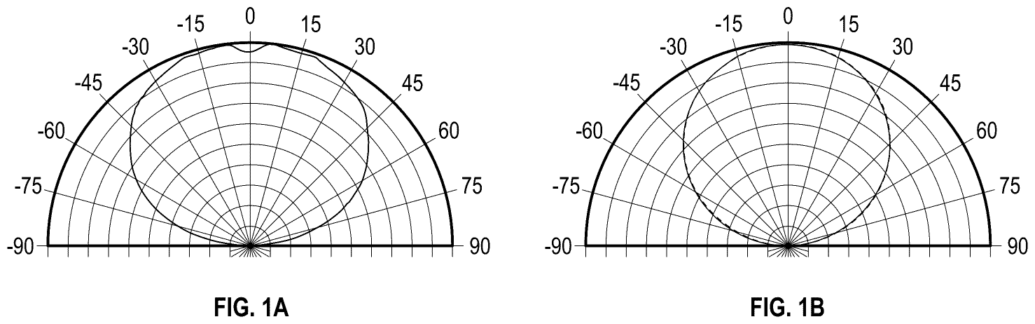

FIG. 1A is an exemplary emission profile for an LED chip that is flip-chip mounted with a sapphire substrate serving as a light-emitting face. In FIG. 1A, the emission angles are plotted with angles as measured from a direction normal to the light-emitting face of the LED chip. As such, an angle of 0° represents the center direction that is perpendicular from the light-emitting face. Light generated in the active LED structure may pass through the sapphire substrate before exiting the chip and contributing to the emission profile. As illustrated in FIG. 1A, lateral waveguiding within the sapphire substrate may cause a dip in emission intensity an angle of 0°. While such an emission profile is acceptable for many LED applications, certain directional applications, including torch, beam, and stage-lighting, among others, may prefer more Lambertian emission profiles. Conventional LED chip structures, such as those where active LED structures are flipped and mounted to carrier substrates with growth substrates removed, have been developed that address the above-described deficiencies of sapphire substrates. However, such techniques typically involve more complex fabrication with increased associated costs.

According to principles of the present disclosure, sapphire substrate structures are disclosed for flip-chip LEDs that provide more Lambertian emission profiles. Such structures included certain substrate thicknesses in combination with various light extraction features provided along the light-emitting face. In this manner, aspects of the present disclosure may provide exemplary emission profiles for flip-chip LEDs with sapphire substrates as illustrated in FIG. 1B. In this regard, increased light emissions are provided at or near 0° angles while decreased light emissions are provided at wider angles, such as +/−30° or more. While embodiments of the present disclosure are described in the context of sapphire substrates, the principles disclosed are equally applicable to other growth substrates that may exhibit lateral waveguiding, including AlN and SiC substrates.

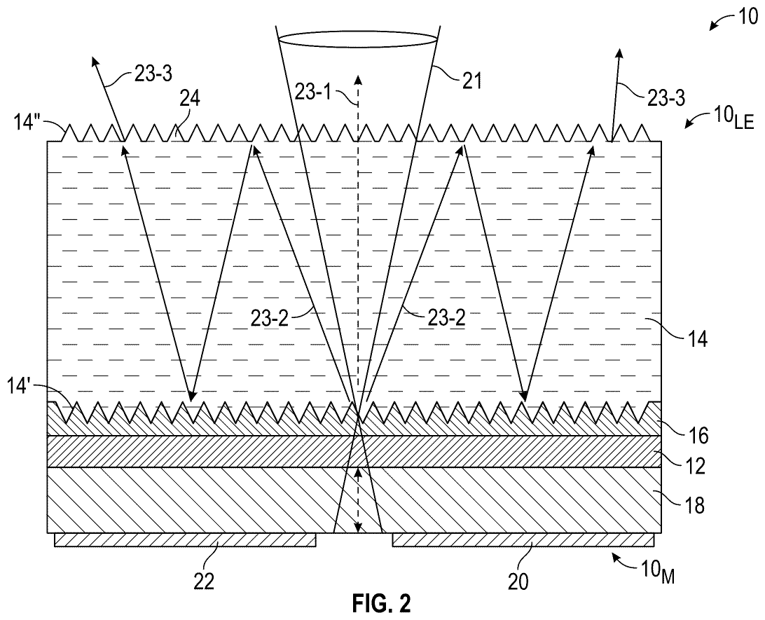

FIG. 2 is a generalized cross-sectional view of an LED chip 10 with a flip-chip orientation according to aspects of the present disclosure. The LED chip includes an active LED structure 12 that is formed on a substrate 14, or growth substrate. In certain embodiments, one or more buffer layers and/or undoped layers 16 may be provided between the substrate 14 and the active LED structure 12. The substrate 14 may embody a patterned substrate such that a first surface 14′ of the substrate 14 closest to the active LED structure 12 is patterned. The first surface 14′ may include multiple recessed and/or raised features that form an interface that enhances light-extraction between the active LED structure 12 and the substrate 14. A number of metallization, dielectric, and/or reflective layers, generally indicated with label 18 in FIG. 2, may be provided on a side of the active LED structure 12 that is opposite the substrate 14. An anode contact 20 and a cathode contact 22 complete the LED chip 10. As illustrated, the anode/cathode side of the LED chip 10 forms a mounting face and an opposing face of the LED chip 10 forms a primary light-emitting face 10_{M}. As illustrated, the primary light-emitting face 10_{LE} corresponds with a second surface 14″ of the substrate 14 that is opposite the first surface 14′. As used herein, the primary light-emitting face 10_{LE} forms the intended light-exiting surface for a majority of light generated by the active LED structure 12.

When the LED chip 10 is electrically activated, light generated within the active LED structure 12 may enter the substrate 14 and follow any number of light-propagation paths. An escape cone 21 illustrates angles of light 23-1 at or near normal to the second surface 14″ that may escape the substrate 14 along a desired emission direction. Light 23-2 that reaches the second surface 14″ with angles outside the escape cone 21 may be laterally re-directed within the substrate 14, thereby forming lateral waveguiding. In certain embodiments, the second surface 14″ of the substrate 14 is formed with light-extraction features 24 that form non-planar surfaces that increase the probability the laterally propagating light 23-2 may escape the second surface 14″ as light 23-3 along a desired emission direction. The light-extraction features 24 may embody raised protrusions from the substrate 14, such as an array of cone-shaped protrusions. In certain embodiments, the light-extraction features 24 are formed in the substrate 14 by a subtractive process, such as etching and/or stamping into the material of the substrate 14. The light-extraction features 24 may form a repeating pattern across one or more portions of the substrate 14. In certain embodiments, the light-extraction features 24 form an array of cone shapes in the second surface 14″. Without the light-extraction features 24, the laterally propagating light 23-2 may continue to non-Lambertian light emissions as illustrated by FIG. 1A. As will be described in greater detail below, dimensions of the light-extraction features 24 along with a thickness of the substrate 14 are disclosed that provide light emission patterns similar to FIG. 1B.

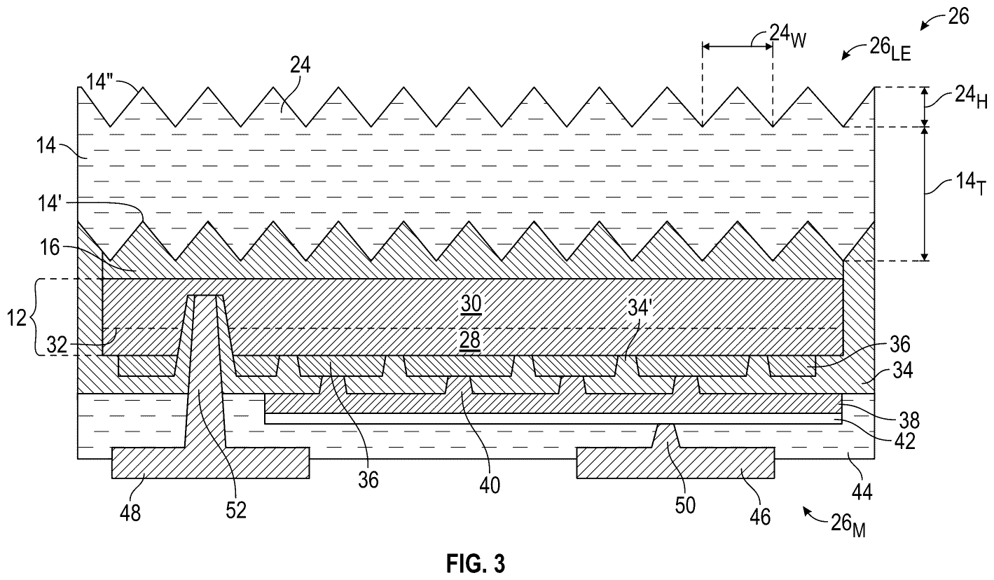

FIG. 3 is a cross-sectional view of a representative LED chip 26 arranged in a flip-chip configuration according to principles of the present disclosure in a similar manner to FIG. 2. As illustrated, the active LED structure 12 generally comprises a p-type layer 28, an n-type layer 30, and an active layer 32 formed on the substrate 14. In certain embodiments, one or more buffer layers and/or undoped layers 16 may be provided between the substrate 14 and the active LED structure 12. The substrate 14 may embody a patterned substrate such that the first surface 14′ of the substrate 14 closest to the active LED structure 12 is patterned as described for FIG. 2. In certain embodiments, the n-type layer 30 is between the active layer 32 and the substrate 14. In other embodiments, the doping order may be reversed. The substrate 14 may comprise many different materials such as sapphire or AlN or SiC, among others, and can have one or more surfaces that are shaped, textured, or patterned to enhance light extraction. In certain embodiments, the substrate 14 is light transmissive (preferably transparent) to wavelengths of light generated by the active layer 32. For example, the substrate 14 may comprise a material that transmits at least 80%, or at least 90%, of light generated by the active LED structure 12. In certain embodiments, the active LED structure 12 comprises group III-Nitride semiconductor materials, or (Al, In, Ga)N materials, and the substrate 14 comprises sapphire.

The LED chip 26 may further include a first reflective layer 34 that is provided on portions of the p-type layer 28 with a current spreading layer 36 therebetween. The first reflective layer 34 may comprise many different materials and preferably comprises a material that presents an index of refraction step with the material of the active LED structure 12 to promote total internal reflection (TIR) of light generated from the active LED structure 12. Light that experiences TIR is redirected without experiencing absorption or loss and can thereby contribute to useful or desired LED chip emission. In certain embodiments, the first reflective layer 34 comprises a material with an index of refraction lower than the index of refraction of the active LED structure 12 material. The first reflective layer 34 may comprise many different materials, with some having an index of refraction less than 2.3, while others can have an index of refraction less than 2.15, less than 2.0, and less than 1.5. In some embodiments, the first reflective layer 34 comprises a dielectric material, with some embodiments comprising silicon dioxide (SiO₂) and/or silicon nitride (SiN). It is understood that many dielectric materials can be used such as SiN, SiNx, Si₃N₄, Si, germanium (Ge), SiO₂, SiOx, titanium dioxide (TiO₂), tantalum pentoxide (Ta₂O₅), indium tin oxide (ITO), magnesium oxide (MgOx), zinc oxide (ZnO), and combinations thereof. In certain embodiments, the first reflective layer 34 may include multiple alternating layers of different dielectric materials, e.g., alternating layers of SiO₂ and SiN that symmetrically repeat or are asymmetrically arranged. Some Group III nitride materials such as GaN can have an index of refraction of approximately 2.4, SiO₂ can have an index of refraction of approximately 1.48, and SiN can have an index of refraction of approximately 1.9. Embodiments with an active LED structure 12 comprising GaN and the first reflective layer 34 comprising SiO₂ can have a sufficient index of refraction step between the two to allow for efficient TIR of light. The first reflective layer 34 can have different thicknesses depending on the type of materials used, with some embodiments having a thickness of at least 0.2 microns (μm). In some of these embodiments, the first reflective layer 34 can have a thickness in the range of 0.2 μm to 0.7 μm, while in some of these embodiments the thickness can be approximately 0.5 μm. Portions of the first reflective layer 34 may extend along mesa sidewalls of the active LED structure 12.

The current spreading layer 36 may embody a layer of conductive material, for example a transparent conductive oxide such as ITO or a metal such as platinum (Pt), although other materials may be used. In certain embodiments, the current spreading layer 36 may continuously cover the p-type layer 28. In other embodiments and as illustrated in FIG. 3, the current spreading layer 36 may be formed with a number of openings or even discontinuous regions that allow portions 34′ of the first reflective layer 34 to extend through the current spreading layer 36 and contact the p-type layer 28. In this manner, interfaces formed between the p-type layer 28 and the first reflective layer 34 that do not include the current spreading layer 36 may exhibit increased reflectivity to light generated by the active LED structure 12. Even though the current spreading layer 36 may not continuously cover the p-type layer 28, the openings or discontinuous regions of the current spreading layer 36 may have small enough lateral dimensions to still suitably spread current along the p-type layer 28.

The LED chip 26 may further include a second reflective layer 38 that is on the first reflective layer 34 such that the first reflective layer 34 is arranged between the active LED structure 12 and the second reflective layer 38. The second reflective layer 38 may include a metal layer that is configured to reflect any light from the active LED structure 12 that may pass through the first reflective layer 34. The second reflective layer 38 can comprise many different materials such as Ag, gold (Au), Al, or combinations thereof. As illustrated, the second reflective layer 38 may include one or more reflective layer interconnects 40 that provide electrically conductive paths through the first reflective layer 34 to the current spreading layer 36. In certain embodiments, the reflective layer interconnects 40 comprise reflective layer vias. Accordingly, the first reflective layer 34, the second reflective layer 38, and the reflective layer interconnects 40 form a reflective structure of the LED chip 26. In some embodiments, the reflective layer interconnects 40 comprise the same material as the second reflective layer 38 and are formed at the same time as the second reflective layer 38. In other embodiments, the reflective layer interconnects 40 may comprise a different material than the second reflective layer 38. The LED chip 26 may also comprise a barrier layer 42 on a side of the second reflective layer 38 opposite the first reflective layer 34 to prevent migration of the second reflective layer 38 material, such as Ag, to other layers. Preventing this migration helps the LED chip 26 maintain efficient operation through its lifetime. The barrier layer 42 may comprise an electrically conductive material, with suitable materials including but not limited to sputtered Ti/Pt followed by evaporated Au bulk material or sputtered Ti/Ni followed by an evaporated Ti/Au bulk material. A passivation layer 44 is included on the barrier layer 42 as well as any portions of the second reflective layer 38 that may be uncovered by the barrier layer 42. The passivation layer 44 may further be arranged on portions of the first reflective layer 34 that are uncovered by the second reflective layer 38. The passivation layer 44 protects and provides electrical insulation for the LED chip 26 and can comprise many different materials, such as a dielectric material. In certain embodiments, the passivation layer 44 is a single layer, and in other embodiments, the passivation layer 44 comprises a plurality of layers. A suitable material for the passivation layer 44 includes but is not limited to SiN, SiNx, and/or Si₃N₄. In certain embodiments, the first reflective layer 34 comprises SiO₂ and the passivation layer 44 comprises SiN, SiNx, or Si₃N₄. In other embodiments, the first reflective layer 34 and at least a portion of the passivation layer 44 may each comprise SiO₂.

In FIG. 3, the LED chip 26 comprises a p-contact 46 and an n-contact 48 that are arranged on the passivation layer 44 and are configured to provide electrical connections with the active LED structure 12. The p-contact 46, which may also be referred to as an anode contact, may comprise one or more p-contact interconnects 50 that extend through the passivation layer 44 to the barrier layer 42 or the second reflective layer 38 to provide an electrical path to the p-type layer 28. In certain embodiments, the one or more p-contact interconnects 50 comprise one or more p-contact vias. The n-contact 48, which may also be referred to as a cathode contact, may comprise one or more n-contact interconnects 52 that extend through the passivation layer 44, the barrier layer 42, the first and second reflective layers 34, 38, the p-type layer 28, and the active layer 32 to provide an electrical path to the n-type layer 30. In certain embodiments, the one or more n-contact interconnects 52 comprise one or more n-contact vias. In operation, a signal applied across the p-contact 46 and the n-contact 48 is conducted to the p-type layer 28 and the n-type layer 30, causing the LED chip 26 to emit light from the active layer 32. The p-contact 46 and the n-contact 48 can comprise many different materials such as Au, copper (Cu), nickel (Ni), In, Al, Ag, tin (Sn), Pt, or combinations thereof. In still other embodiments, the p-contact 46 and the n-contact 48 can comprise conducting oxides and transparent conducting oxides such as ITO, nickel oxide (NiO), ZnO, cadmium tin oxide, indium oxide, tin oxide, magnesium oxide, ZnGa₂O₄, ZnO₂/Sb, Ga₂O₃/Sn, AgInO₂/Sn, In₂O₃/Zn, CuAlO₂, LaCuOS, CuGaO₂, and SrCu₂O₂. The choice of material used can depend on the location of the contacts and on the desired electrical characteristics, such as transparency, junction resistivity, and sheet resistance. As described above, the LED chip 26 is arranged for flip-chip mounting and the p-contact 46 and n-contact 48 are configured to be mounted or bonded to a surface, such as a printed circuit board. As such, the p-contact 46 and n-contact 48 are arranged on a mounting surface 26_{M} of the LED chip 26, and the second surface 14″ of the substrate 14 forms a light-emitting face 26_{LE} of the LED chip 26.

In FIG. 3, a thickness 14_{T} of the substrate 14 along with heights 24_{H} and widths 24_{W} of the light-extraction features 24 are provided that reduce lateral waveguiding and provide light emission patterns similar to FIG. 1B. For illustrative purposes, relative dimensions of the light-extraction features 24 may be exaggerated in FIG. 3. According to aspects of the present disclosure, the thickness 14_{T} of the substrate 14 may be less than or equal to 100 μm, or less than or equal to 75 μm, or less than or equal to 60 μm, or less than or equal to 50 μm, or less than or equal to 25 μm, or less than or equal to 10 μm, or ranges defined by any of the above specified values with 0.5 μm as a lower boundary. Thickness values above 100 μm may exhibit undesirable levels of lateral waveguiding, particularly for directional lighting applications. According to further aspects of the present disclosure, heights 24_{H} and widths 24_{W} of the light-extraction features 24 may be provided that are greater than about 0.5 μm, or in a range from 0.5 μm to 10 μm, among other ranges. In certain embodiments, the heights 24_{H} and/or widths 24_{W} of the light-extraction features 24 may be larger, such as up to about 100 μm, or even a same or similar value as a thickness of the substrate 14. It has also been found that regardless of actual dimensions, average height 24_{H} to width 24_{W} ratios (i.e., height 24_{H} divided by width 24_{W}) for individual light-extraction features 24 across the substrate 14 provided in a range from 0.3 to 1, or in a range from 0.3 to 0.7, or in a range from 0.3 to 0.6 may provide improved Lambertian emission patterns across all of the above-specified thickness 14_{T} values.

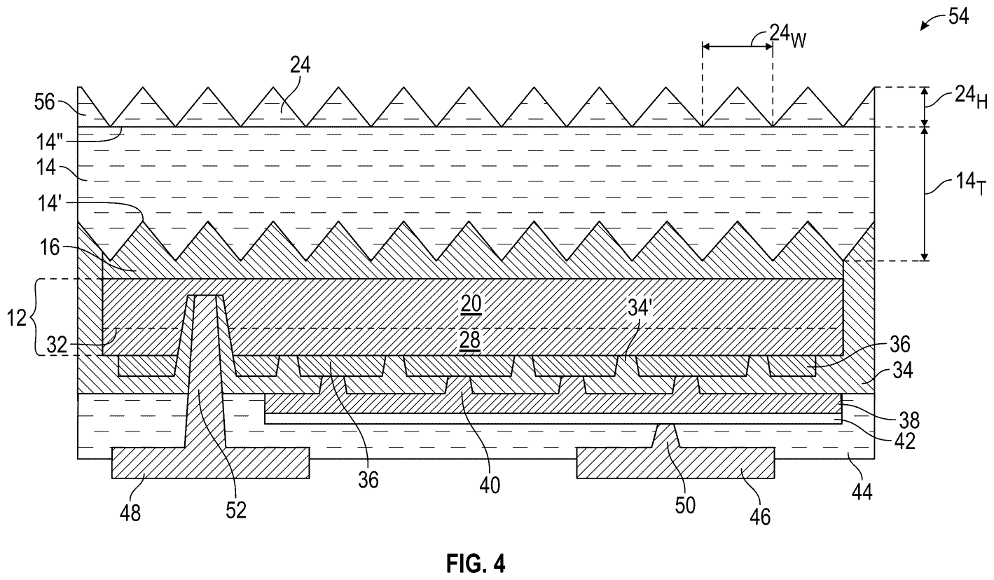

FIG. 4 is a cross-sectional view of an LED chip 54 that is similar to the LED chip 26 of FIG. 3, except the light-extraction features 24 are formed in an additional layer 56 on the second surface 14″ of the substrate 14. Rather than forming the light-extraction features 24 directly into portions of the substrate 14 as illustrated in FIG. 3, the light-extraction features 24 of FIG. 4 are formed in the additional layer 56. In certain embodiments, the additional layer 56 may comprise a material that is light-transmissive and/or light-transparent to wavelengths of light generated by the active layer 32. For example, the additional layer 56 may comprise a material that transmits at least 80%, or at least 90%, of light from the active LED structure 12. Exemplary materials for the additional layer 56 include glass, silicon nitride, SiO₂, and silicone. The light-extraction features 24 may be pre-formed in the additional layer 56 before it is applied to the substrate 14. In other embodiments, the light-extraction features 24 may be formed in the additional layer 56 after it is added to the substrate 14. In certain embodiments, the heights 24_{H} and widths 24_{W} of the light-extraction features 24 in the additional layer 56 may be the same as described above for FIG. 3.

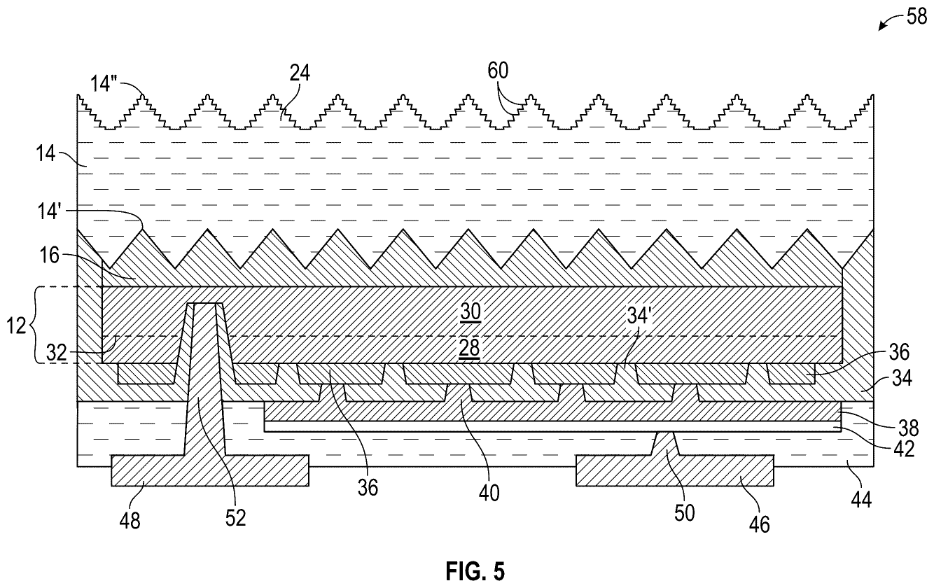

FIG. 5 is a cross-sectional view of an LED chip 58 that is similar to the LED chip 26 of FIG. 3, except surfaces of the light-extraction features 24 may include additional light-extraction features 60 formed thereon. In this regard, the additional light-extraction features 60 may have smaller dimensions than the larger light-extraction features 24 and further increase the likelihood of light escaping the substrate 14. In certain embodiments, the additional light-extraction features 60 may have heights and/or widths that are less than the light-extraction features 24, such as less than 0.5 times, or less than 0.3 times, or less than 0.1 times the heights 24_{H} and/or widths 24_{W} of the light-extraction features 24. While the light-extraction features 24 may be formed in a repeating pattern across the substrate 14, the additional light-extraction features 60 may be formed in an irregular arrangement, such as random texturing along sidewalls or side surfaces of the light-extraction features 24. In certain embodiments, the additional light-extraction features 60 may be formed simultaneously with the larger light-extraction features 24. For example, the light-extraction features 24 may be formed by a laser ablation process and operating parameters of the laser ablation may be adjusted to form the irregularities of the additional light-extraction features 60. In other embodiments, the additional light-extraction features 60 may be formed in a subsequent step, such as plasma etching through a mask that is applied to the larger light-extraction features 24. In a specific example, a solution of nanoparticles may be spin coated over the light-extraction features 24 such that the nanoparticles form various nano etch masks that are distributed along the light-extraction features 24. The additional light-extraction features 60 may then be formed by an etching process, such as plasma etching, through the nano etch masks. After etching, the nanoparticles may be removed.

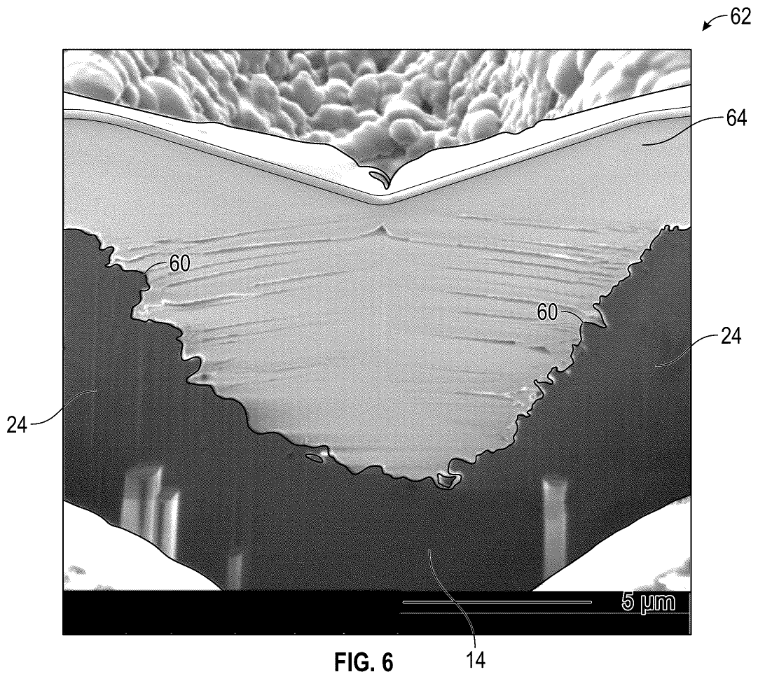

FIG. 6 is a focused ion beam (FIB) image of a portion of an LED chip 62 that is similar to the LED chip 58 of FIG. 5. The FIB image is taken from a portion of the LED chip 62 between two adjacent light-extraction features 24. A platinum bar 64 for the FIB image is visible in FIG. 6 and is not part of the LED chip 62. As illustrated, the additional light-extraction features 60 are formed along sidewalls or side surfaces of the larger light-extraction features 24. The additional light-extraction features 60 may effectively form irregular or randomly textured surfaces for the light-extraction features 24, thereby increasing the likelihood of incident light escaping and reducing instances of lateral waveguiding within the substrate 14.

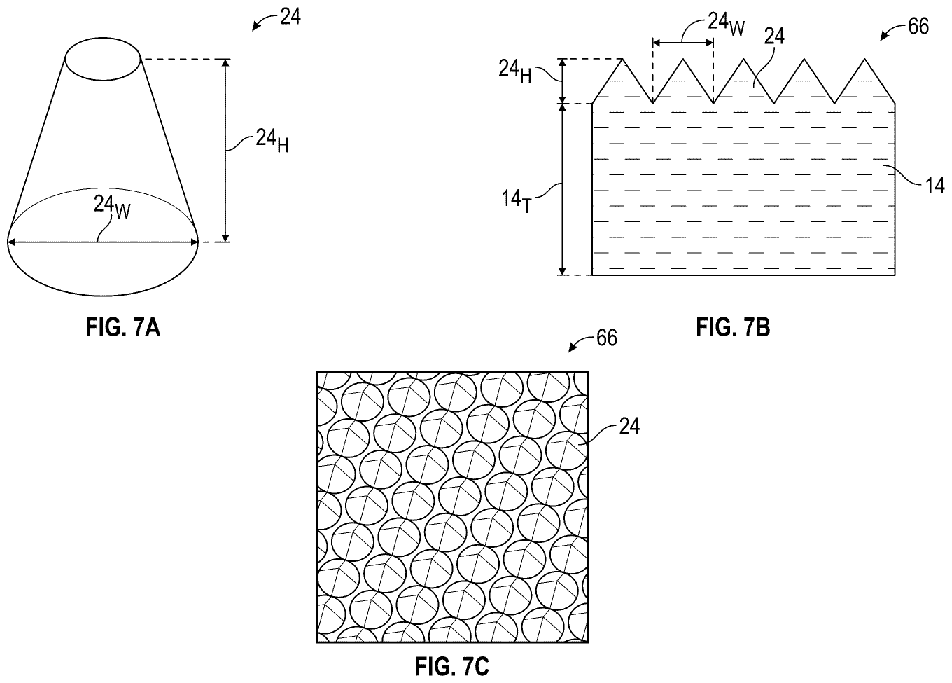

As described above, unique combinations of the above-described substrate thicknesses and dimensions of light-extraction features are disclosed that provide Lambertian or near Lambertian emission profiles in flip-chip LED structures with growth substrates. Light behavior within substrates was investigated in simulations and experimentally validated to determine relationships between the substrate thicknesses and light-extraction features. FIGS. 7A to 7B illustrate various simulation parameters that were investigated as proof of concept. FIG. 7A illustrates a single light-extraction feature 24 with labels for the height 24_{H} and width 24_{W} described above. In the context of cone-shapes, the width 24_{W} may correspond to a diameter at a base of the cone. FIG. 7B is a view of a portion of an LED chip 66 that is similar to the LED chip 26 of FIG. 3, although the principles disclosed are applicable to the structures of FIGS. 4 and 5. As illustrated, the thickness 14_{T} of the substrate 14 is measured from a base of the light-extraction features 24. FIG. 7C is a top view of the portion of the LED chip 66 illustrating the light-extraction features 24 arranged with an array layout.

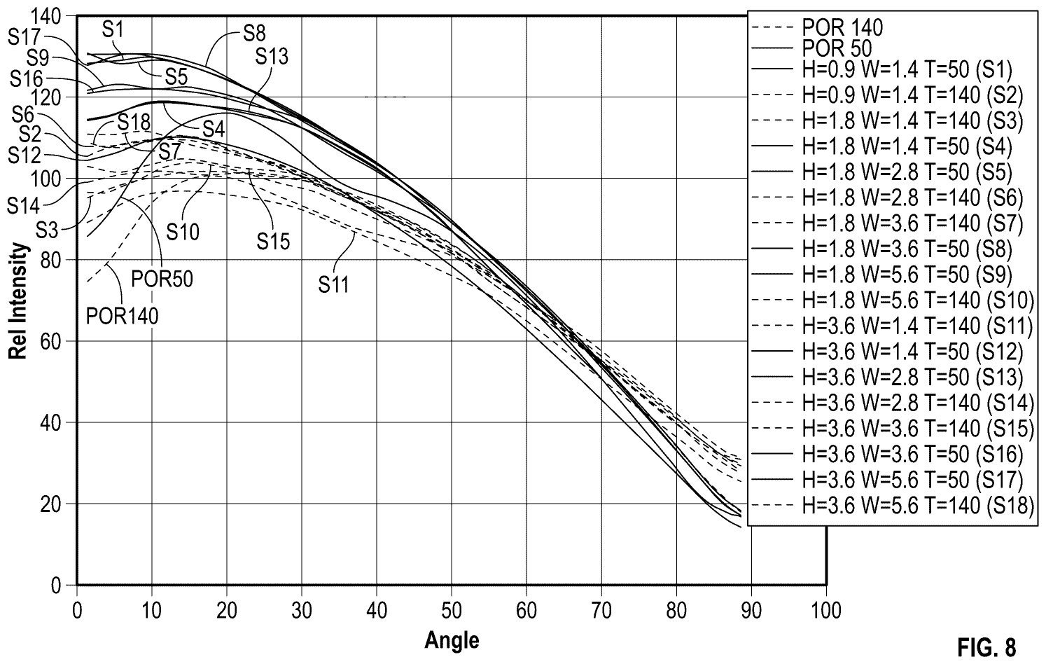

FIG. 8 is a plot illustrating relative intensity vs. emission angle for a variety of combinations of heights 24_{H} and widths 24_{W} of the light-extraction features 24 and thickness 14_{T} of the substrate 14 as illustrated in FIGS. 7A and 7B. In FIG. 8, a first process of record (POR140) data line is provided that illustrates a standard flip-chip LED structure with a thickness 14_{T} of 140 μm for the substrate 14 and no light-extraction elements. Notably, the POR140 intensity exhibits a substantial decrease at or near an angle of 0°, which corresponds with a center direction normal to the light-emitting surface of the LED chip. The PORI 40 intensity is highest at angles between about 15° and 25°. A second data line POR50 corresponds to the chip structure for PORI 40, but with a reduced thickness 14_{T} of the substrate 14 to 50 μm, again without light-extraction elements. The POR50 intensity is higher than the PORI 40, however POR50 still exhibits a substantial decrease in intensity at or near an angle of 0°. In this manner, reductions in the thickness 14_{T} of the substrate 14 alone may not be enough to provide Lambertian emission profiles. The remainder of the samples S1 to S18 correspond with various combinations of heights 24_{H} and widths 24_{W} of the light-extraction features 24 and thickness 14_{T} of the substrate 14, all of which show increased intensities at or near 0°. Pairs of samples include common heights 24_{H} and widths 24_{W} with thickness 14_{T} values of either 50 μm or 140 μm. For example, sample S1 includes an arrangement where the height 24_{H} is 0.9 μm, the width 24_{W} is 1.4 μm, and the thickness 14_{T} is 50 μm while sample S2 includes an arrangement where the height 24_{H} is 0.9 μm, the width 24_{W} is 1.4 μm, and the thickness 14_{T} is 140 μm. In general, combinations of lower thickness 14_{T} values, lower heights 24_{H}, and higher widths 24_{W} exhibited highest emission intensities at angles from 0° and 20°.

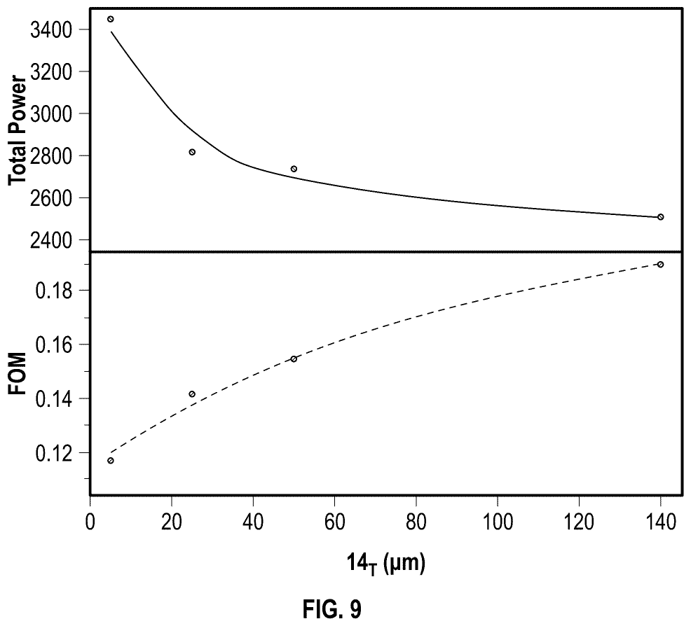

FIG. 9 is a chart illustrating figure of merit (FOM) values for evaluating the various thickness 14_{T} values of FIG. 8 for samples that include light-extraction features. For targeting a more Lambertian emission profile, the FOM is derived as a ratio of a total power of emission intensity at edge emissions compared with a total power of emission intensity across all angles. Edge emissions are defied as angles greater than 60° from FIG. 8. In this regard, the FOM may be defined as an area under the curve in FIG. 8 for angles greater than 60° divided by a total area under the curve for all emission angles from 0° to in FIG. 8. As such, the FOM may also be referred to as an edge emission ratio of an emission profile for an LED chip. In FIG. 9, the total power of emission intensity for all angles begins to substantially increase at substrate thicknesses from 50 μm and below. Additionally, the FOM, which is based on edge emissions above 60°, exhibits noticeable decreases at substrate thicknesses 14_{T} from 50 μm and below, indicative of increased directional emissions from 0° to 60°. The FOM also is below 0.2, or below 0.18 for substrate thicknesses 14_{T} from 100 μm and below. Accordingly, smaller values for the thickness 14_{T} along with the presence of the light-extraction features provides more Lambertian emission profiles in flip-chip LED structures with growth substrates.

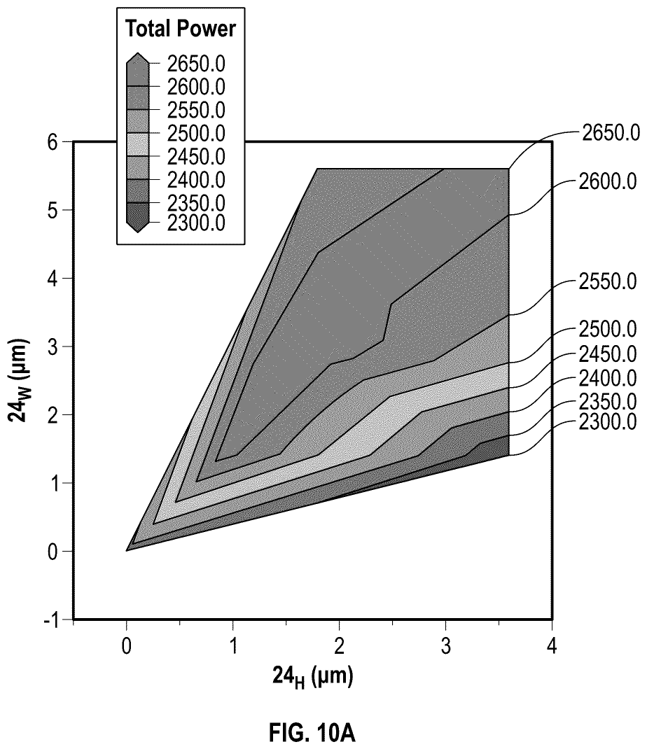

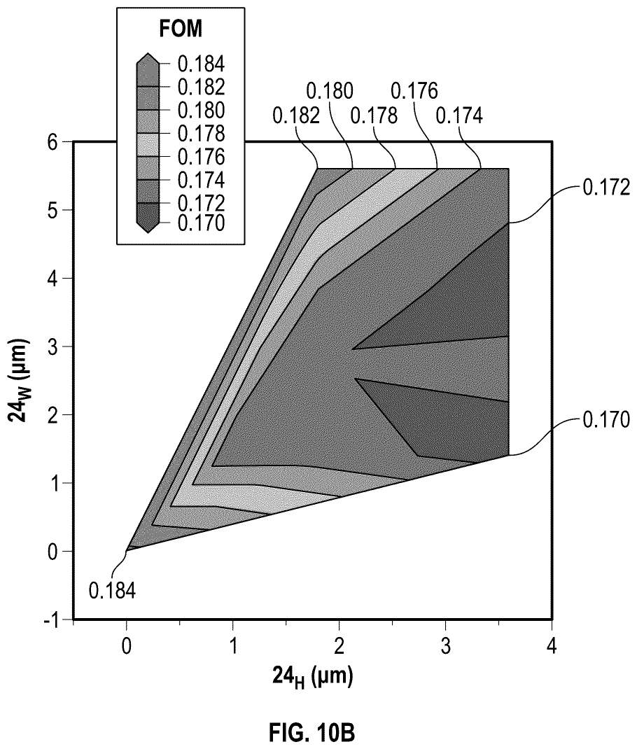

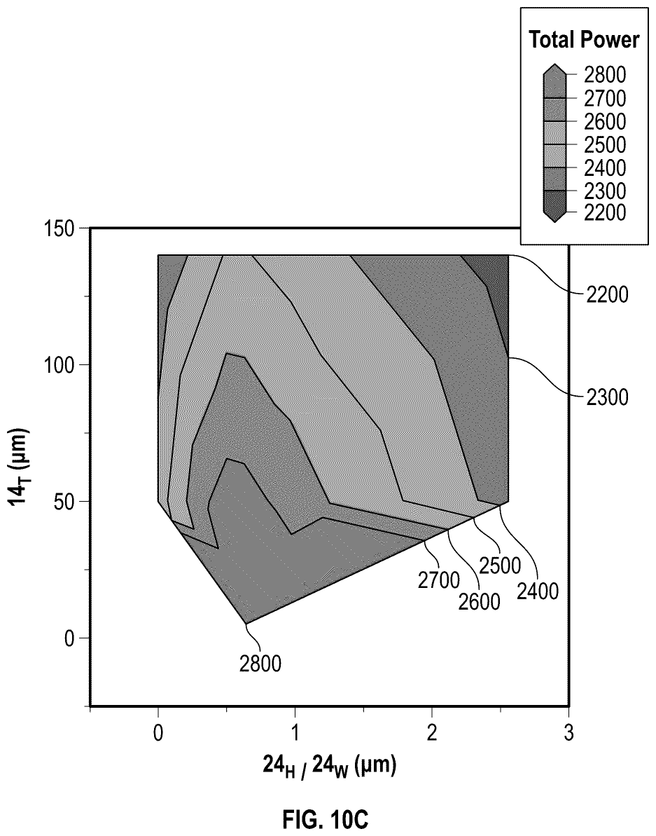

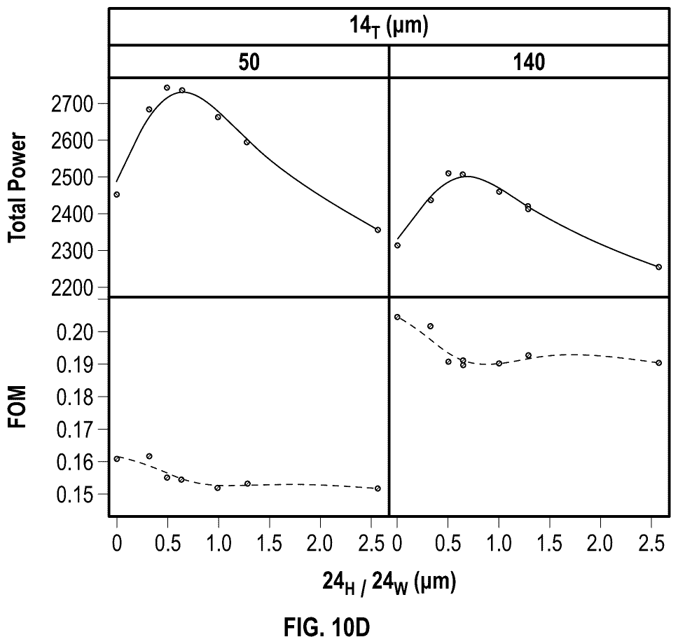

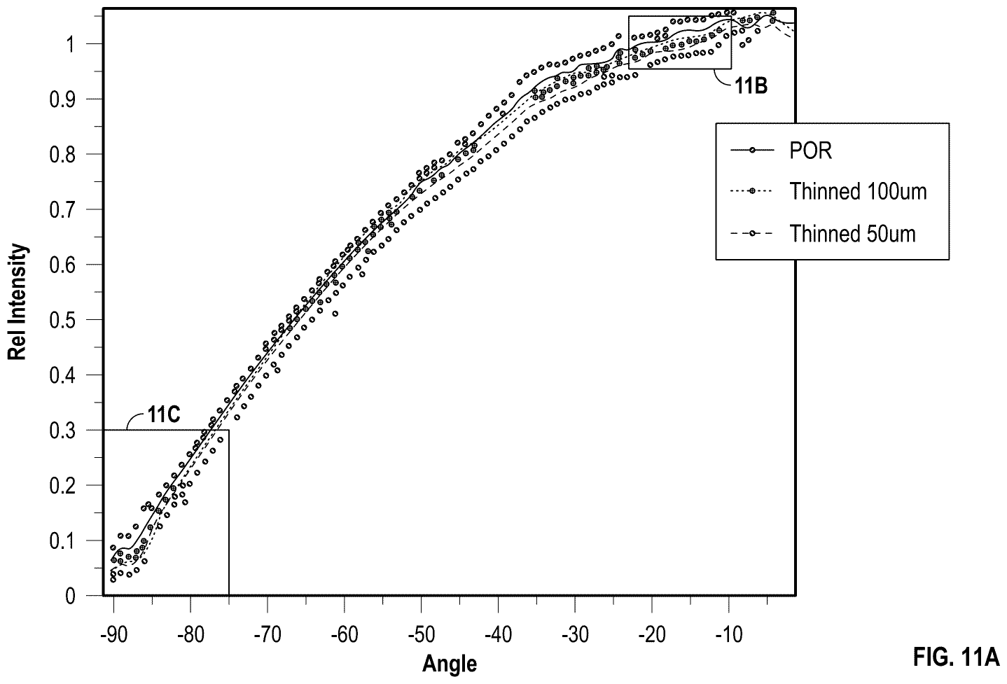

FIGS. 10A to 10D are charts for evaluating dimensions of the light-extraction elements from the LED chips plotted in FIG. 8. FIG. 10A is a contour plot illustrating relationships between heights 24_{H} and widths 24_{W} of the light-extraction features 24 by total power for all emission angles of FIG. 8. As illustrated, larger dimensions for the heights 24_{H} and widths 24_{W} generally result in increased total power, although highest total powers for particular values of either the heights 24_{H} or widths 24_{W} do not directly follow. For example, for a width 24_{W} of 3 μm, the highest total power values are exhibited at heights 24_{H} between about 1.3 μm and 2.5 μm, with total power values decreasing for heights 24_{H} above 2.5 μm.

FIG. 10B is a contour plot illustrating relationships between heights 24_{H} and widths 24_{W} of the light-extraction features 24 by FOM for all emission angles of FIG. 8. In a similar manner as in FIG. 10A, FOM values generally exhibit intended reductions with larger dimensions for the heights 24_{H} and widths 24_{W}. However, in a similar manner as the total power of FIG. 10A, the FOM values to not directly follow within particular values for the heights 24_{H} and widths 24_{W}. In this manner, particular ratios of the height 24_{H} to the width 24_{W} was found to be important for providing highest total power values and lowest FOM values.

FIG. 10C is a contour plot illustrating relationships between ratios of the heights 24_{H} to the widths 24_{W} of the light-extraction features 24 for various thickness 14_{T} values. Notably, average height 24_{H} to width 24_{W} ratios in a range from 0.3 to 1, or in a range from 0.3 to 0.7, or in a range from 0.3 to 0.6 exhibited highest total powers for each thickness 14_{T} value while total powers increased with each decreasing thickness 14_{T} values. Additionally, the ranges for height 24_{H} to width 24_{W} ratios even expanded at lower thickness 14_{T} values. For example, for thickness 14_{T} values between 25 μm and 50 μm, height 24_{H} to width 24_{W} ratios could be in a range from 0.3 to 1.5 to produce highest total powers.

FIG. 10D is a plot comparing height 24_{H} to width 24_{W} ratios by FOM and total power values for thickness 14_{T} values of 40 μm and 140 μm. As with FIGS. 10A-10C, it is demonstrated that average height 24_{H} to width 24_{W} ratios in a range from 0.3 to 1, or in a range from 0.3 to 0.7, or in a range from 0.3 to 0.6 exhibited desired high total power values with low FOM values, regardless of the thickness 14_{T} value. Increased total power values may further be realized with the lower thickness 14_{T} values.

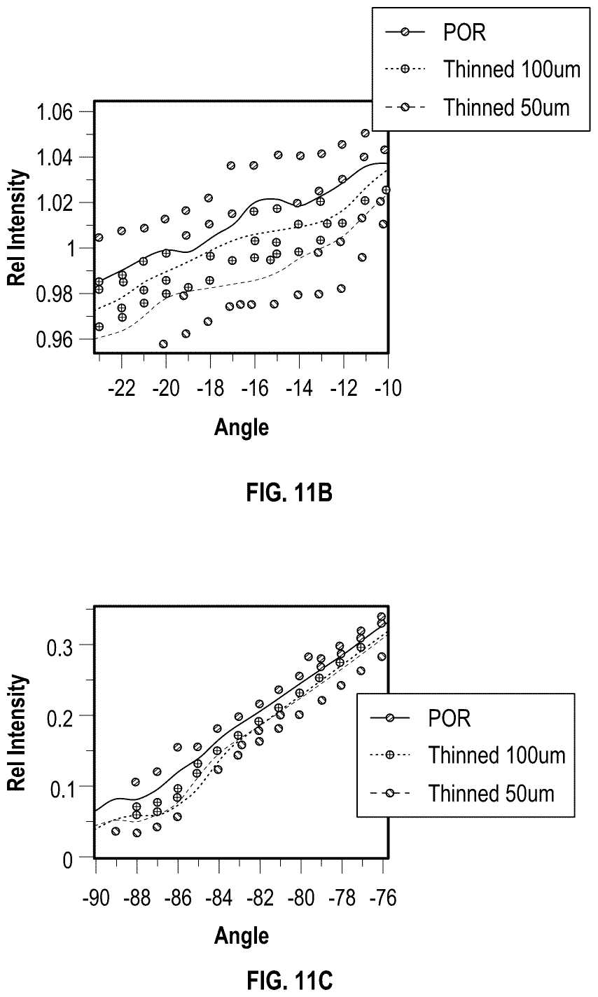

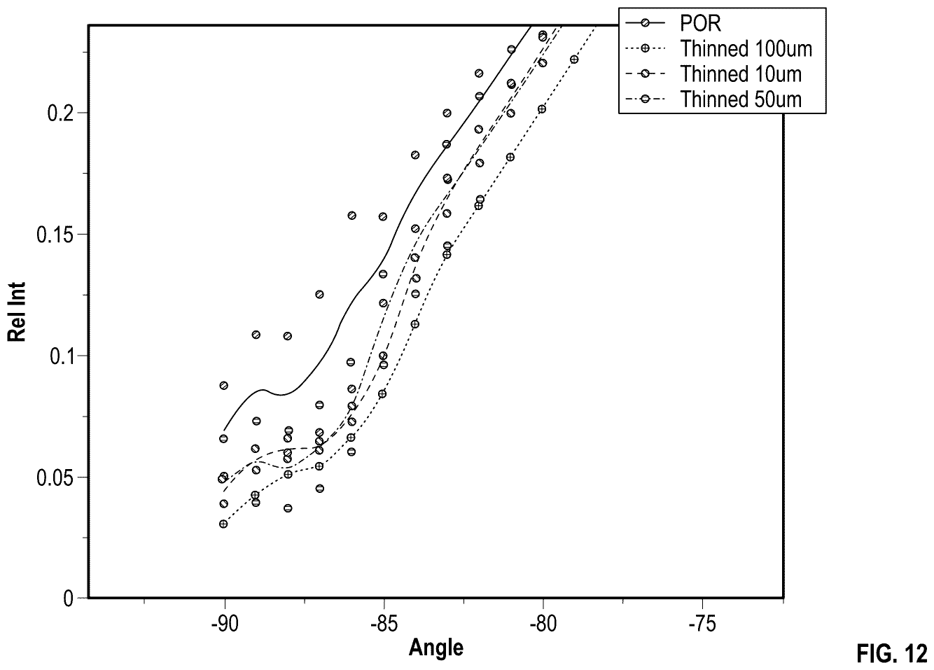

The simulation results, including the discovery of the height 24_{H} to width 24_{W} ratios by substrate thickness 14_{T}, were experimentally validated as illustrated in the plots of FIGS. 11 to 13. FIG. 11A is a plot showing experimental results comparing relative intensity over emission angle for a POR chip with a flip-chip structure and a growth substrate with a thickness of about 140 μm without light-extraction features. FIG. 11B is a view of a portion of the plot of FIG. 11A taken from the box labeled 11B in FIG. 11A. FIG. 11C is a view of a portion of the plot of FIG. 11A taken from the box labeled 11C in FIG. 11A. Experimental data was also collected for a same chip structure, just with substrate thickness values of 100 μm and 50 μm. As illustrated, for edge emission angles in a range from 85° to 90°, intensity values decreased, indicative of reduced lateral waveguiding as described above. FIG. 12 is a plot showing experimental results comparing relative intensity over emission angle in a manner similar to FIG. 11A with an additional sample having a substrate thickness of 10 μm. Again, edge emission angles exhibit decreased intensities for reduced thickness substrates.

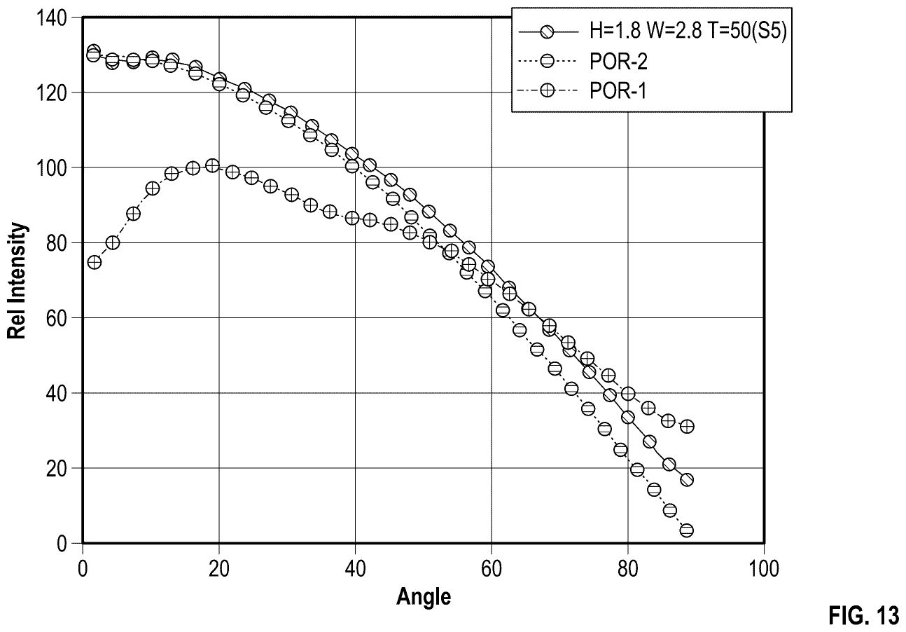

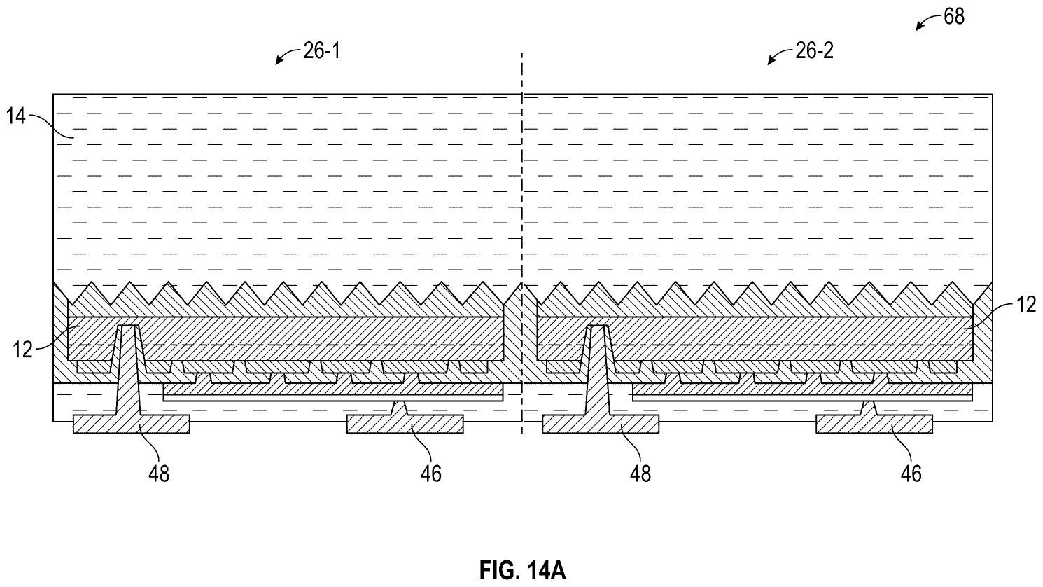

FIG. 13 is a plot comparing experimental results for relative intensity over emission angle for the POR chip of FIGS. 11 and 12 (labeled as POR-1 in FIG. 13, a conventional LED chip where the growth substrate is removed (labeled as POR-2), and an exemplary LED chip fabricated according to the sample S5 of FIG. 8. In this regard, the S5 structure includes an arrangement where the height 24_{H} is 1.8 μm, the width 24_{W} is 2.8 μm, and the thickness 14_{T} is 50 μm. As illustrated, the presence of the growth substrate (e.g., sapphire) in the POR-1 chip exhibits decreased emission intensities at emission angles from 0° to about 15°. The conventional LED chip POR-2 with the growth substrate removed such that the active LED structure is flipped and bonded to a carrier submount exhibits more Lambertian emissions. However, as described above, such a chip structure may be associated with more complex structures and increased costs. The LED chip with the S5 structure according to aspects of the present disclosure exhibits a similar intensity distribution with the POR-2 chip, thereby demonstrating that the combinations of the above-described substrate thicknesses and dimensions of light-extraction features may provide Lambertian or near Lambertian emission profiles in flip-chip LED structures with growth substrates.

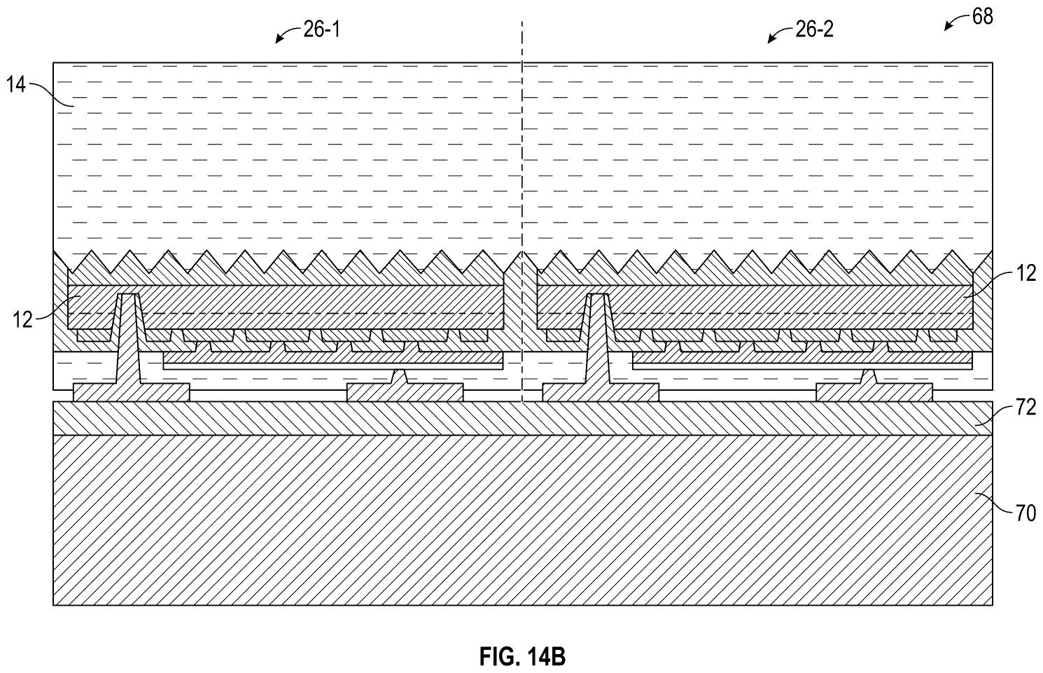

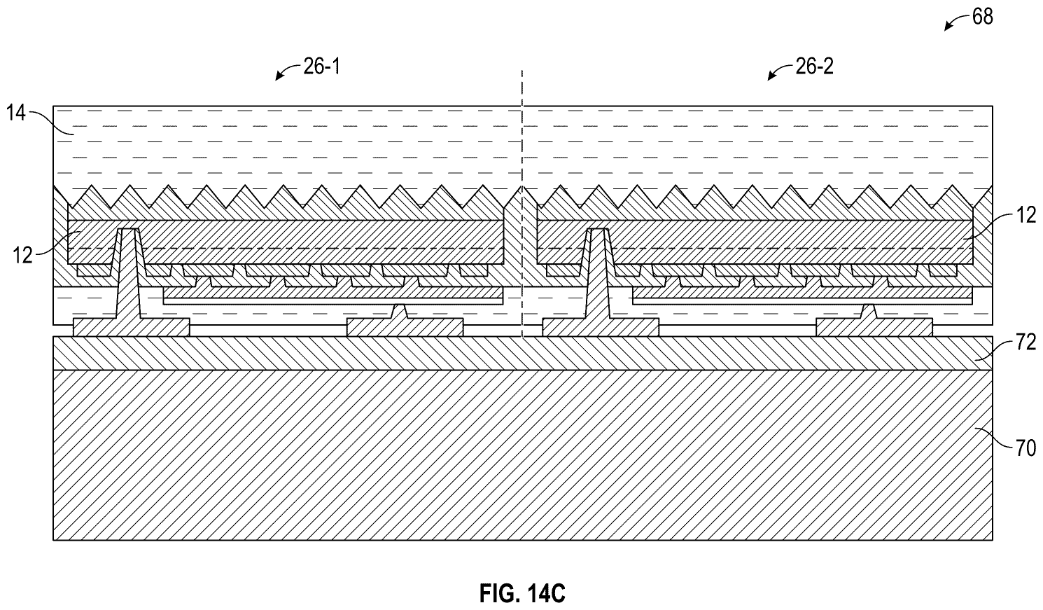

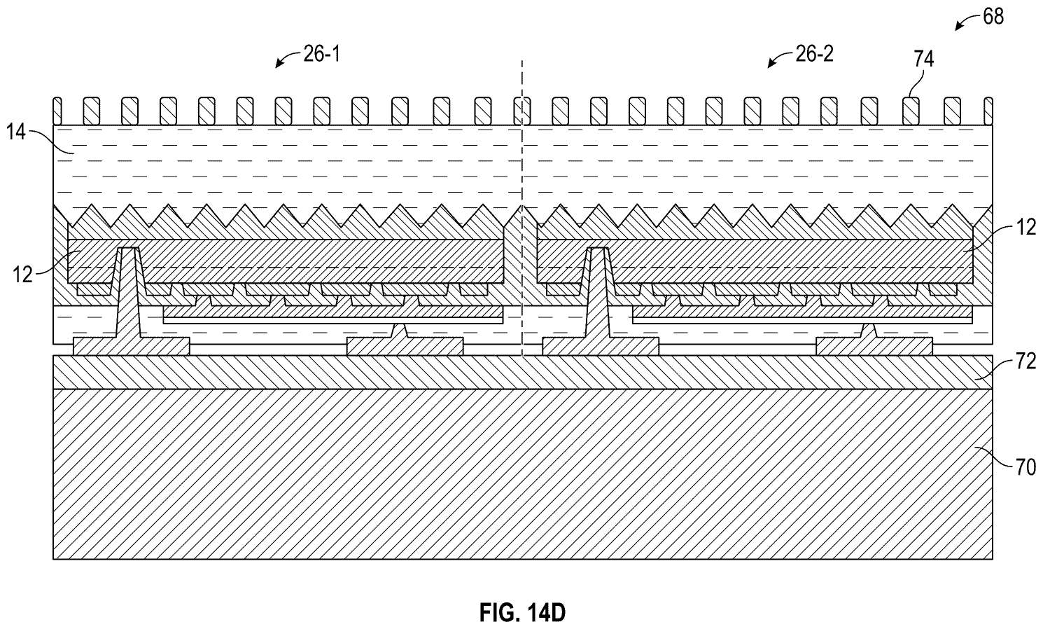

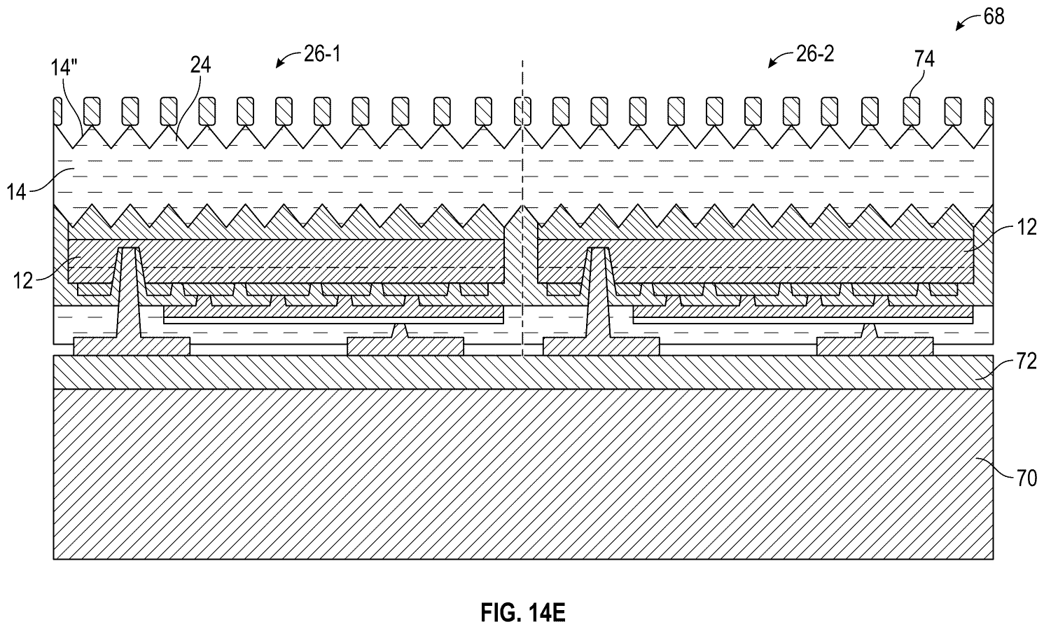

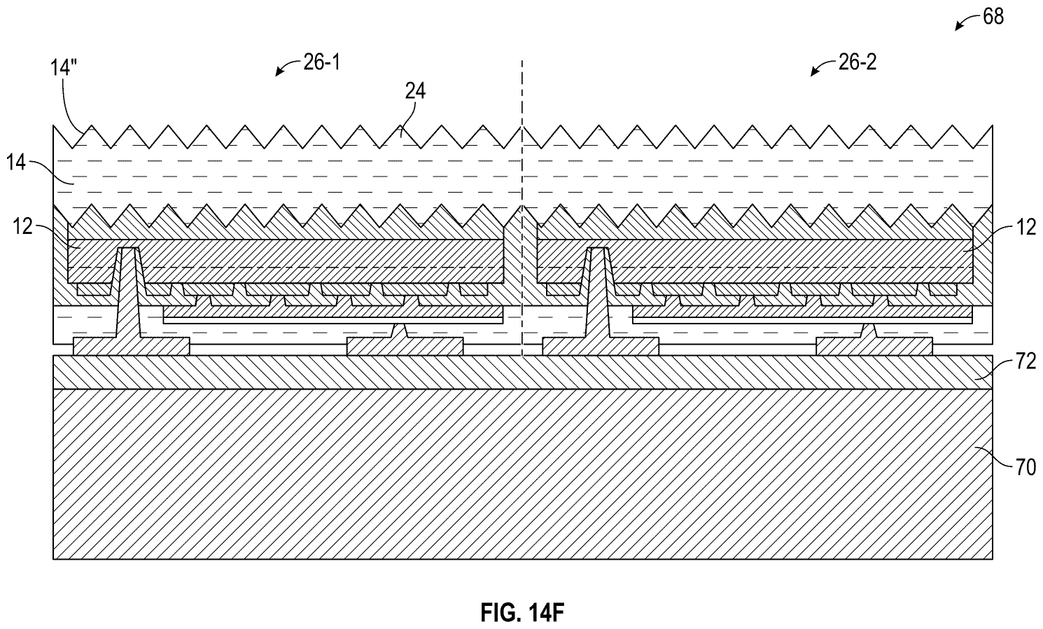

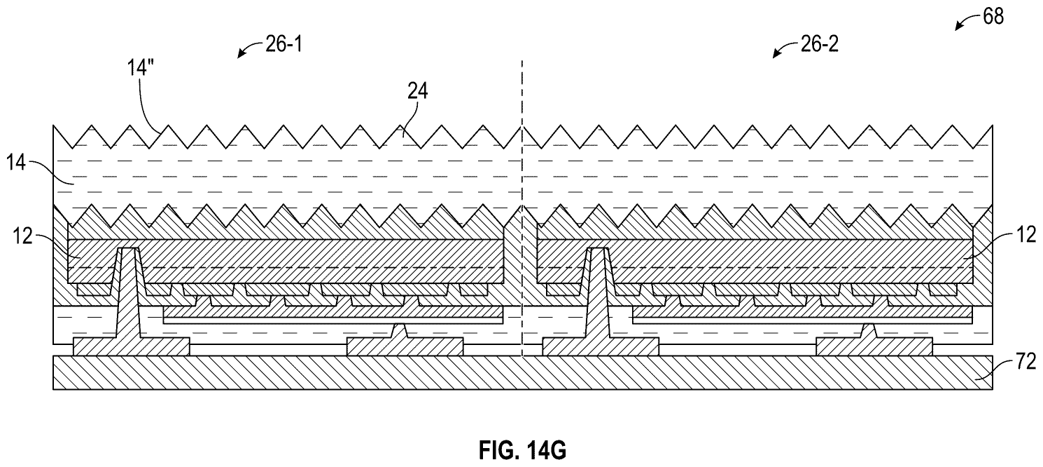

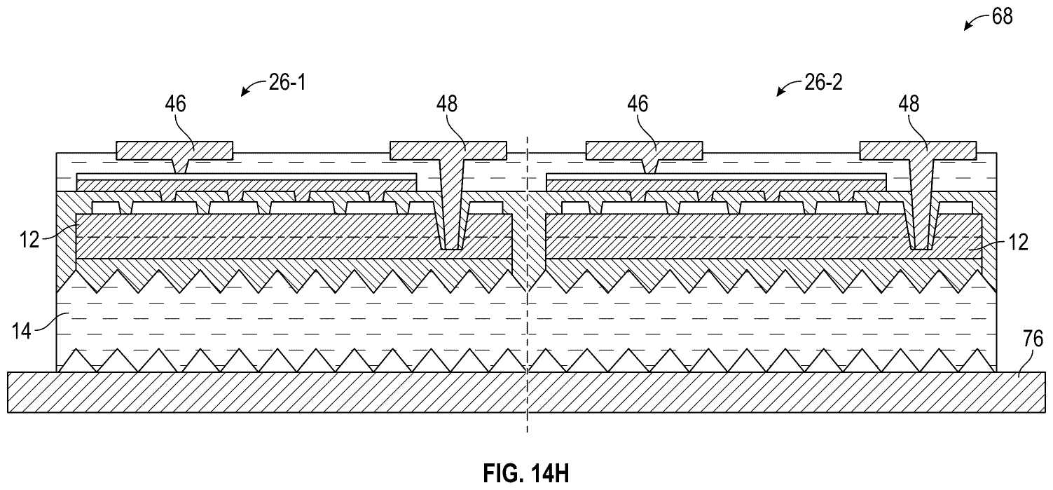

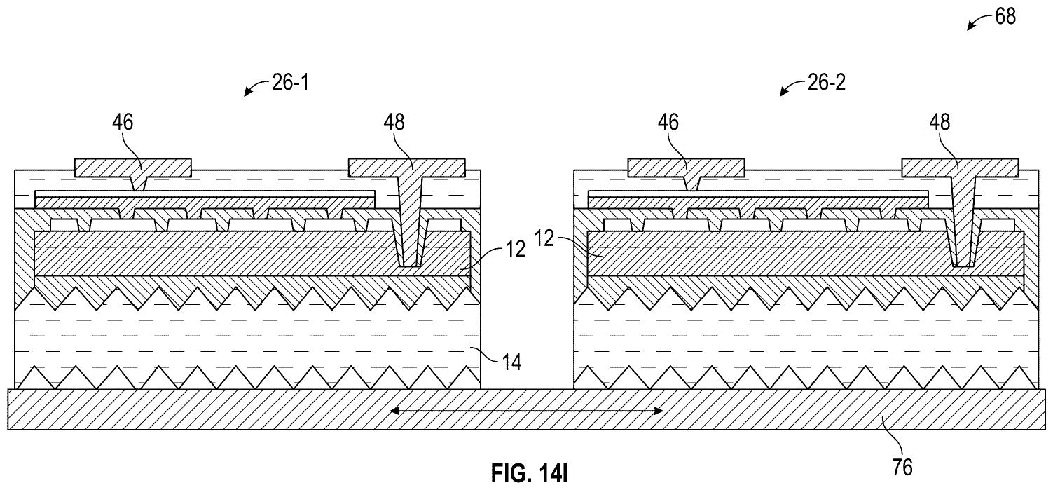

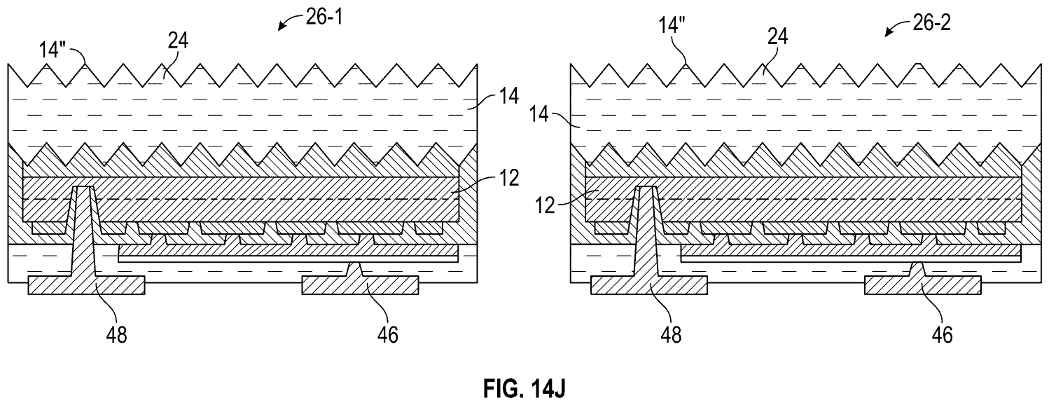

FIGS. 14A to 14J illustrate an exemplary fabrication sequence for manufacturing LED chips as illustrated in FIG. 3. However, unless otherwise specified below, many of the same fabrication steps are also applicable to the LED structures illustrated in FIGS. 4 and 5. LED chips are commonly fabricated in bulk on larger growth substrates before singulation into individual devices. For illustrative purposes, the fabrication sequences are illustrated in the context of two LED chips 26-1, 26-2 formed in bulk. However, it is understood that in practice, many more LED chips are formed simultaneously before singulation.

FIG. 14A is a cross-sectional view of a bulk LED wafer 68 at a fabrication sequence where elements of the LED chip 26 of FIG. 3 have been formed for each of the LED chips 26-1, 26-2 on the substrate 14. A vertical dashed line indicates a future dicing line where the individual LED chips 26-1, 26-2 will be separated from one another. In FIG. 14A, the substrate 14 is continuous between the LED chips 26-1, 26-2. FIG. 14B is a cross-sectional view of the bulk LED wafer 68 of FIG. 14A at a subsequent fabrication step where the LED wafer 68 is bonded to a temporary carrier 70 by way of a temporary bonding media 72. The temporary carrier 70 may embody another sapphire substrate or other rigid material that supports the LED chips 26-1, 26-2 during thinning of the substrate 14 at a subsequent step.

FIG. 14C is a cross-sectional view of the bulk LED wafer 68 of FIG. 14B at a subsequent fabrication step after the substrate 14 has been thinned. In certain embodiments, the substrate 14 may be thinned by a planarization process that mechanically and/or chemically grinds the substrate 14 to reduce the thickness thereof. Material of the bonding media 72 should be selected to accommodate stresses between the active LED structures 12 and the thinning substrate 14. For example, the material of the bonding media 72 may require a bond with increased rigidity, otherwise associated stresses between the active LED structures 12 and the thinned substrate 14 can increase instances of tearing and/or delamination of the active LED structures 12 from the substrate 14.

FIG. 14D is a cross-sectional view of the bulk LED wafer 68 of FIG. 13C at a subsequent fabrication step after a photomask 74 is applied to the substrate 14. The photomask 74 may be patterned on the substrate 14 to determine locations for the light-extraction features 24 as illustrated in FIG. 14E. FIG. 14E is a cross-sectional view of the bulk LED wafer 68 of FIG. 14D at a subsequent fabrication step after an etching process, such as dry etching, has been applied to the substrate 14 and the photomask 74 to form the light-extraction features 24 in the second surface 14″ of the substrate 14.

FIG. 14F is a cross-sectional view of the bulk LED wafer 68 of FIG. 14E at a subsequent fabrication step after the photomask 74 is removed. In alternative embodiments, the light-extraction features 24 as illustrated in FIG. 14F may be formed by other fabrication sequences that do not involve etching with the photomask 74 of FIGS. 14D and 14E. For example, the light-extraction features 24 may be formed by embossing or stamping associated patterns into the substrate 14. FIG. 14G is a cross-sectional view of the bulk LED wafer 68 of FIG. 14F at a subsequent fabrication step after the temporary carrier 70 is removed. FIG. 14H is a cross-sectional view of the bulk LED wafer 68 of FIG. 14G at a subsequent fabrication step after the bulk LED wafer 68 is mounted on a film frame 76 or die tape. In certain embodiments, the bulk LED wafer 68 may be inverted such that the substrate 14 is adjacent the film frame 76. At any of the fabrication steps for FIGS. 14F to 14H, dicing streets or dicing lanes may be formed in the substrate 14 that define singulation lines for the individual LED chips 26-1, 26-2. The dicing streets may correspond with the vertical dashed lines in FIGS. 14F to 14H and may be provided by forming subsurface laser damage within the substrate 14. Other dicing techniques may involve mechanical sawing through the substrate 14.

FIG. 14I is a cross-section of the bulk LED wafer 68 of FIG. 14H at a subsequent fabrication step after the film frame 76 is stretched to separate the individual LED chips 26-1, 26-2. In certain embodiments, portions of the substrate 14 may break along the dicing streets described above to form the individual LED chips 26-1, 26-2 as illustrated in FIG. 14J. As illustrated in FIG. 14J, each individual LED chip 26-1, 26-2 includes a portion of the active LED structure 12 and the substrate 14 with light-extraction features 24.

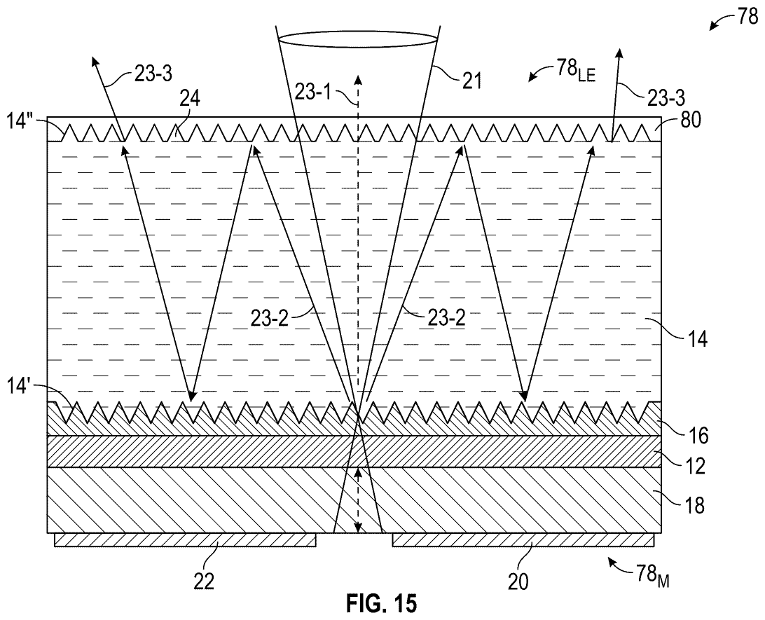

FIG. 15 is a cross-sectional view of an LED chip 78 that is similar to the LED chip 10 of FIG. 2 and further includes an antireflective layer 80 on the second surface 14″ of the substrate and on the light-extraction features 24. As illustrated, a primary light-emitting face 78_{LE} is associated with the second surface 14″ of the substrate 14 and a mounting face 78M is associated with the first surface 14′ of the substrate 14. The antireflective layer 80 may be configured to further enhance light extraction from the substrate 14 in combination with the light-extraction features 24. As used herein, the antireflective layer 80 or coating may include one or more layers that provide an index of refraction that is selected to reduce the reflection or refraction of light at interfaces with the substrate 14 and/or the light extraction features 24. In certain embodiments, the antireflective layer 80 may comprise single or multiple thin layers that transition from the index of refraction of the substrate 14 and/or the light extraction features 24 to the surrounding environment. The surrounding environment may comprise encapsulation layers, lumiphoric material layers, and even air. In this regard, the antireflective layer 80 may provide a graded index of refraction with values in a range between a first index of refraction associated with the substrate 14 and/or the light extraction features 24 and a second index of refraction associated with a surrounding environment. Advantageously, by positioning the antireflective layer 80 as described, abrupt index of refraction changes may be avoided, which may reduce the amount of light reflected internally. The antireflective layer 80 may form a coating that partially covers the light-extraction features 24 or entirely covers the light-extraction features 24 as illustrated. The antireflective layer 80 may be readily added to any of the previously described embodiments.

The antireflective layer 80 may include many different materials, including but not limited to one or more oxides of silicon (e.g., SiO₂), oxides of zirconium (e.g., ZrO₂), oxides of aluminum (e.g., Al₂O₃), oxides of titanium (e.g., TiO₂), oxides of indium (e.g., In₂O₃), indium tin oxide (ITO), silicon nitride (e.g., SiNx), magnesium fluoride (e.g., MgF₂), cerium fluoride (e.g., CeF₃), flouropolymers, and combinations thereof. For embodiments where the antireflective layer 80 comprises a multi-layer structure, relative thicknesses of sub-layers may comprise one or more combinations of quarter-wavelength and half-wavelength values of target light, for example the wavelength of light emitted by the LED chip 78.

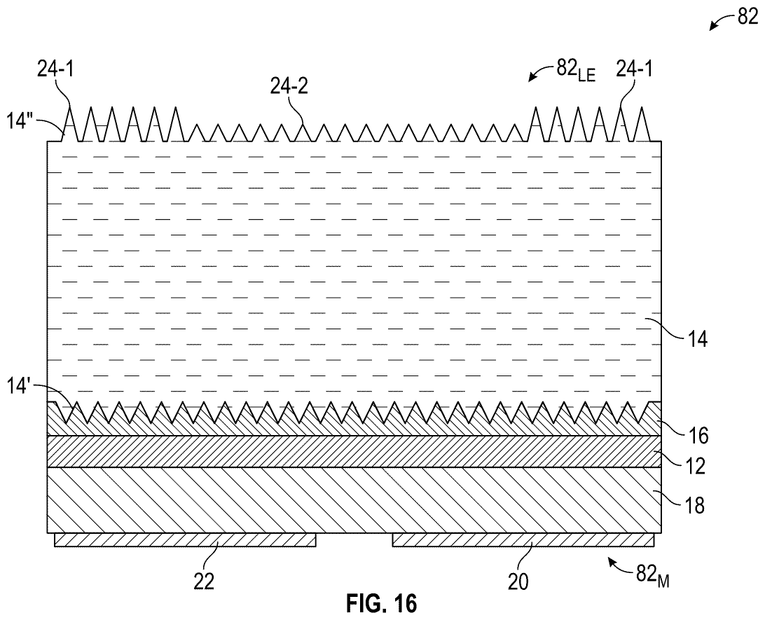

FIG. 16 is a cross-sectional view of an LED chip 82 that is similar to the LED chip 10 of FIG. 2 for embodiments where relative sizes and/or shapes of light-extraction features 24-1, 24-2 are variable along the LED chip 82 for tailoring light output of the LED chip 82. Rather than being arranged in a uniform manner across the LED chip 82, the light-extraction features 24-1, 24-2 may have different sizes and/or shapes in different regions for localized tailoring of emissions. For example, a first group of light-extraction features 24-1 may be arranged along a perimeter of the LED chip 82 with a different size and/or shape than a centrally arranged second group of light-extraction features 24-2. In this regard, localized beam shaping may be provided. As indicated in at least FIG. 8, decreasing heights for common widths of the light-extraction features 24-1, 24-2 may generally provide increased light extraction. As such, when the light-extraction features 24-1 at or near the perimeter of the LED chip 82 have taller heights than the light-extraction features 24-2, increased emissions may be provided along central portions of the LED chip 82. Such an arrangement may be beneficial for Lambertian emission profile targets. The above-described differences may also be accomplished by varying the width alone or the height-to-width ratios between the light-extraction features 24-1, 24-2. In other embodiments, the arrangement of the light-extraction features 24-1, 24-2 may be reversed to increase light extraction along perimeter edges, depending on the target emission profile. In still further embodiments, various shapes of the light-extraction features 24-1, 24-2 may be provided, such as tilted cones or pyramids, that preferentially direct highest intensity light emissions off center from 0° emission angles to target angled emission patterns. The variable size and/or shape of the light-extraction features 24-1, 24-2 may be readily added to any of the previously described embodiments.

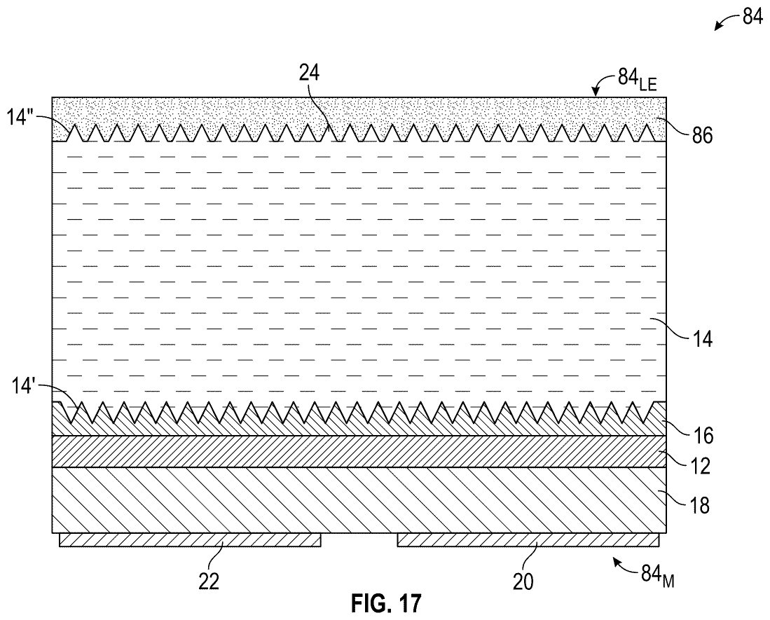

FIG. 17 is a cross-sectional view of an LED chip 84 that is similar to the LED chip 10 of FIG. 2 for embodiments where the LED chip 84 includes a lumiphoric material 86 on a primary light-emitting face 84_{LE} that is opposite a mounting face 84_{M}. The lumiphoric material 86 may comprise a single layer or multiple layers that are formed on the LED chip 84. The lumiphoric material 86 may include lumiphoric particles, such as phosphor particles, that convert portions of light generated by the active LED structure 12 to one or more different wavelengths. By arranging the lumiphoric material 86 on the light-extraction features 24 as illustrated, increased light may be injected into the lumiphoric material 86 for wavelength conversion. In particular, each light-extraction feature 24 is arranged to protrude into the lumiphoric material 86, effectively surrounding each light-extraction feature 24 with the lumiphoric material 86. As such, light that escapes the substrate 14 via the light-extraction features 24 may be directly injected into the lumiphoric material 84 without passing through intervening layers. While the lumiphoric material 84 is illustrated on the second surface 14″ of the substrate 14, the lumiphoric material 84 may further be arranged along sidewalls of the substrate 14 that extend between the second surface 14″ and the first surface 14′.

While the above-described embodiments are described in the context of sapphire growth substrates in flip-chip LED arrangements, the principles disclosed are applicable to improving and/or altering emission patterns and increasing brightness for other growth substrates in flip-chip orientations, such as AlN and SiC, among others.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip comprising:
a substrate comprising a first surface and a second surface that opposes the first surface, the substrate comprising a thickness that is less than or equal to 100 microns (μm);
an active LED structure on the first surface of the substrate, the active LED structure being configured to generate light that passes through the substrate when electrically activated; and
a plurality of light-extraction features formed at the second surface of the substrate, each light-extraction feature of the plurality of light-extraction features comprising a height and a width, and an average ratio of the height to the width for individual light-extraction features of the plurality of light-extraction features is in a range from 0.3 to 1.

2. The LED chip of claim 1, wherein the average ratio of the height to the width is in a range from 0.3 to 0.7.

3. The LED chip of claim 1, wherein the thickness of the substrate is less than or equal to 75 μm.

4. The LED chip of claim 1, wherein:
the average ratio of the height to the width is in a range from 0.3 to 0.7; and
the thickness of the substrate is less than or equal to 60 μm.

5. The LED chip of claim 1, wherein the active LED structure comprises group III-Nitride semiconductor materials and the substrate comprises sapphire.

6. The LED chip of claim 1, wherein the substrate comprises aluminum nitride.

7. The LED chip of claim 1, wherein the substrate comprises silicon carbide.

8. The LED chip of claim 1, wherein the substrate comprises a material that transmits at least 90% of the light from the active LED structure.

9. The LED chip of claim 1, wherein the plurality of light-extraction features comprise a same material as the substrate.

10. The LED chip of claim 1, wherein the plurality of light-extraction features are formed in an additional layer that is on the second surface of the substrate.

11. The LED chip of claim 10, wherein the additional layer comprises at least one of glass, silicon nitride, silicone dioxide, and silicone.

12. The LED chip of claim 10, wherein the additional layer comprises a material that transmits at least 90% of the light from the active LED structure.

13. The LED chip of claim 1, wherein additional light-extraction features are formed on side surfaces of one or more light-extraction features of the plurality of light-extraction features.

14. The LED chip of claim 1, wherein:
the plurality of light-extraction features form a repeating pattern across the substrate; and the additional light-extraction features are formed in an irregular arrangement along the side surfaces.

15. The LED chip of claim 1, wherein the substrate and the plurality of light-extraction features are configured to provide an emission profile of light exiting the substrate with an edge emission ratio defined as an emission intensity of light with emission angles greater than 60 degrees from a direction normal to the second surface to a total emission intensity of light for all emission angles from 0 to 90 degrees from the direction normal to the second surface, the edge emission ratio being less than 0.2.

16. The LED chip of claim 1, further comprising an antireflective layer on the plurality of light-extraction features.

17. The LED chip of claim 1, wherein a first group of light-extraction features of the plurality of light-extraction features comprises at least one of a different height or width than a second group of light-extraction features of the plurality of light-extraction features.

18. The LED chip of claim 1, further comprising a lumiphoric material on the plurality of light-extraction features.

19. A light-emitting diode (LED) chip comprising:
a substrate comprising a first surface and a second surface that opposes the first surface, the substrate comprising sapphire with a thickness that is less than or equal to 100 microns (μm);
an active LED structure on the first surface of the substrate, the active LED structure being configured to generate light that passes through the substrate when electrically activated; and
a plurality of light-extraction features formed at the second surface of the substrate.

20. The LED chip of claim 19, further comprising an n-contact and a p-contact electrically coupled to the active LED structure, wherein the n-contact and the p-contact are arranged for flip-chip mounting such that the second face of the substrate forms a primary light-emitting face.

21. The LED chip of claim 19, wherein each light-extraction feature of the plurality of light-extraction features comprises a height and a width, and an average ratio of the height to the width for individual light-extraction features of the plurality of light-extraction features is in a range from 0.3 to 1.

22. The LED chip of claim 21, wherein:
the average ratio of the height to the width is in a range from 0.3 to 0.7; and
the thickness of the substrate is less than or equal to 60 μm.

23. The LED chip of claim 19, wherein the plurality of light-extraction features comprise a same material as the substrate.

24. The LED chip of claim 19, wherein the plurality of light-extraction features are formed in an additional layer that is on the second surface of the substrate.

25. The LED chip of claim 24, wherein the additional layer comprises at least one of glass, silicone dioxide, and silicone.

26. The LED chip of claim 19, wherein additional light-extraction features are formed on side surfaces of one or more light-extraction features of the plurality of light-extraction features.

27. The LED chip of claim 26, wherein:
the plurality of light-extraction features form a repeating pattern across the substrate; and
the additional light-extraction features are formed in an irregular arrangement along the side surfaces.

28. The LED chip of claim 19, further comprising an antireflective layer on the plurality of light-extraction features.

29. The LED chip of claim 19, wherein a first group of light-extraction features of the plurality of light-extraction features comprises at least one of a different height or width than a second group of light-extraction features of the plurality of light-extraction features.

30. The LED chip of claim 19, further comprising a lumiphoric material on the plurality of light-extraction features.

31. A method comprising:
providing a light-emitting diode (LED) wafer comprising a substrate with a first surface and a second surface that opposes the first surface and an active LED structure on the first surface of the substrate;
thinning the substrate to a thickness that is less than or equal to 100 microns (μm);
forming a plurality of light-extraction features at the second surface of the substrate after said thinning the substrate; and
separating a plurality of LED chips from the LED wafer, each LED chip of the plurality of LED chips comprising a portion of the active LED structure and a portion of the substrate with light-extraction features of the plurality of light-extraction features.

32. The method of claim 31, wherein each light-extraction feature of the plurality of light-extraction features comprises a height and a width, and an average ratio of the height to the width for individual light-extraction features of the plurality of light-extraction features is in a range from 0.3 to 1.

33. The method of claim 32, wherein:
the average ratio of the height to the width is in a range from 0.3 to 0.7; and
the thickness of the substrate is less than or equal to 60 μm.

34. The method of claim 31, further comprising bonding the LED wafer to a temporary carrier before said thinning the substrate and removing the temporary carrier after said forming the plurality of light-extraction features.

35. The method of claim 31, wherein forming the plurality of light-extraction features comprises etching the substrate through a patterned photomask.

36. The method of claim 31, further comprising forming additional light-extraction features on side surfaces of one or more light-extraction features of the plurality of light-extraction features.
